(19) United States
(12) Patent Application Publication
(10) Pub. No.: US 2019/0164581 A1
(43) Pub. Date: May 30, 2019

(54) SENSE AMPLIFIER WITH COMPARISON NODE BIASING FOR NON-VOLATILE MEMORY

(71) Applicant: SanDisk Technologies LLC, Plano, TX (US)

(72) Inventors: HAO NGUYEN, San Jose, CA (US); GOPINATH BALAKRISHNAN, Santa Clara, CA (US); CHANG SIAU, Cupertino, CA (US); SEUNGPIL LEE, San Ramon, CA (US)

(73) Assignee: SanDisk Technologies LLC, Plano, TX (US)

(21) Appl. No.: 16/031,778

(22) Filed: Jul. 10, 2018

Related U.S. Application Data
(60) Provisional application No. 62/592,404, filed on Nov. 30, 2017.

(51) Int. Cl. G11C 7/08; G11C 7/06; G11C 7/12; G11C 8/08; G11C 16/26

(52) U.S. Cl. CPC G11C 7/08; G11C 7/062; G11C 2207/063; G11C 8/08; G11C 16/26; G11C 7/12

(57) ABSTRACT

Apparatuses, systems, and methods are disclosed for current sensing for non-volatile memory. A current to voltage conversion circuit may convert a current coupled to a sense amplifier to an analog voltage at a sense node. A voltage to digital conversion circuit may convert an analog voltage at a sense node to a digital signal, based on a voltage difference between the sense node and a comparison node during a strobe time. A bias circuit may bias a comparison node to a bias voltage other than a reference voltage, at least during a strobe time.

### CROSS-REFERENCES TO RELATED APPLICATIONS

This application claims the benefit of U.S. Provisional Patent Application No. 62/592,404 entitled “SENSE AMPLIFIER WITH SOURCE BIASING FOR NON-VOLATILE MEMORY” and filed on Nov. 30, 2017 for Hao Nguyen et al., and claims the benefit of U.S. Provisional Patent Application No. 62/596,665 entitled “SENSE AMPLIFIER WITH SOURCE BIASING FOR NON-VOLATILE MEMORY” and filed on Dec. 8, 2017 for Hao Nguyen et al., each of which is incorporated herein by reference.

### TECHNICAL FIELD

The present disclosure, in various embodiments, relates to sense amplifiers and more particularly relates to sense amplifiers with comparison node biasing for non-volatile memory.

### BACKGROUND

Various types of memory store data in arrays of memory cells. A data value is stored in a cell altering a physical or electrical property of a cell such as a stored charge, material phase, electrical resistance, magnetization, or the like. The range of possible values for the data-encoding physical or electrical property is divided into states, so that each state corresponds to a possible data value. For example, a cell with two states may store a 1 if the cell is in the first state, or a 0 if the cell is in a second state. Similarly, a cell with four states may store two bits, so that each of the four states corresponds to one of the four possible two-bit data values. However, errors may occur over time if a cell drifts from one state into another state. Thus, wider ranges of possible values for the data-encoding physical or electrical property may facilitate high-reliability storage by using wider states to decrease the likelihood of error, and/or may facilitate high-density storage by dividing the range into a larger number of states.

Sense amplifiers may be used to convert low-power or analog electrical signals to digital signals with logic levels used by other logic components. Sensing the state of a memory cell, for a read operation or a write verify operation, may include biasing one or more lines connected to a cell, such as a word line, a bit line, and/or a source line, and sensing an analog electrical signal, such as a voltage or current, via a bit line, to determine the state of the cell. A sense amplifier may be coupled to the bit line to convert the convert the analog electrical signal to a data value or logic level. Different biases may be used to distinguish between different states. However, limitations of the sense amplifier may limit bias voltages or currents, thus limiting the usable range of values for the cell.

### SUMMARY

Apparatuses are presented for current sensing. In one embodiment, a sense amplifier includes a current to voltage conversion circuit configured to convert a current coupled to the sense amplifier to an analog voltage at a sense node. In a certain embodiment, a voltage to digital conversion circuit is configured to convert an analog voltage at a sense node to a digital signal, based on a voltage difference between the sense node and a comparison node during a strobe time. In a further embodiment, a bias circuit is configured to bias a comparison node to a bias voltage other than a reference voltage at least during a strobe time.

Systems are presented for data storage. In one embodiment, an array of memory cells stores data. In a certain embodiment, memory cells are coupled to bit lines such that bit line currents during a sense operation correspond to memory cell states. In a further embodiment, a plurality of sense amplifiers output data results based on bit line currents. In one embodiment, a sense amplifier includes a capacitor coupled to a sense node. In a certain embodiment, an isolation transistor couples a capacitor to a bit line for a predetermined sense time such that a voltage at a sense node is based on a bit line current. In a further embodiment, a sense transistor outputs a data result during a strobe time based on a gate to source voltage. In one embodiment, a gate of a sense transistor is coupled to a sense node, and a source terminal of the sense transistor is biased to a bias voltage other than a reference voltage at least during a strobe time.

An apparatus, in another embodiment, includes means for converting a bit line current to an analog voltage at a sense node of a sense amplifier. In a certain embodiment, an apparatus includes means for converting an analog voltage to a binary data value based on a voltage difference between a sense node and a comparison node during a strobe time. In a further embodiment, an apparatus includes means for biasing a comparison node to a bias voltage between a positive supply voltage and ground at least during a strobe time.

### BRIEF DESCRIPTION OF THE DRAWINGS

A more particular description is included below with reference to specific embodiments illustrated in the appended drawings. Understanding that these drawings depict only certain embodiments of the disclosure and are not therefore to be considered to be limiting of its scope, the disclosure is described and explained with additional specificity and detail through the use of the accompanying drawings, in which:

FIG. 1 is a schematic block diagram of one embodiment of a system comprising sense amplifiers;

FIG. 2 is a schematic block diagram illustrating one embodiment of a non-volatile storage device comprising sense amplifiers;

FIG. 3 is a schematic block diagram illustrating one embodiment of an apparatus for accessing non-volatile memory;

FIG. 4 is a schematic diagram illustrating one embodiment of bias voltages for a NAND string;

FIG. 5 is a schematic diagram illustrating another embodiment of bias voltages for a NAND string;

FIG. 6 is a graph illustrating a distribution of threshold voltages for cells of a non-volatile memory device, in one embodiment;

FIG. 7 is a schematic block diagram illustrating one embodiment of a sense amplifier;

FIG. 8 is a schematic block diagram illustrating a further embodiment of a sense amplifier;

FIG. 9 is a timing diagram illustrating operation of a sense amplifier, in one embodiment;

FIG. 10 is a schematic block diagram illustrating layers of an integrated circuit comprising a sense amplifier;

FIG. 11 is a schematic block diagram illustrating a metal interconnect layer for an integrated circuit;

FIG. 12 is a schematic block diagram illustrating a CMOS layer for an integrated circuit; and

FIG. 13 is a schematic flow chart diagram illustrating one embodiment of a method for current sensing.

### DETAILED DESCRIPTION

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like.

Modules may also be implemented at least partially in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may include a single instruction, or many instructions, and may even be distributed over several different code segments, among different programs, across several memory devices, or the like. Where a module or portions of a module are implemented in software, the software portions may be stored on one or more computer readable and/or executable storage media. Any combination of one or more computer readable storage media may be utilized. A computer readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

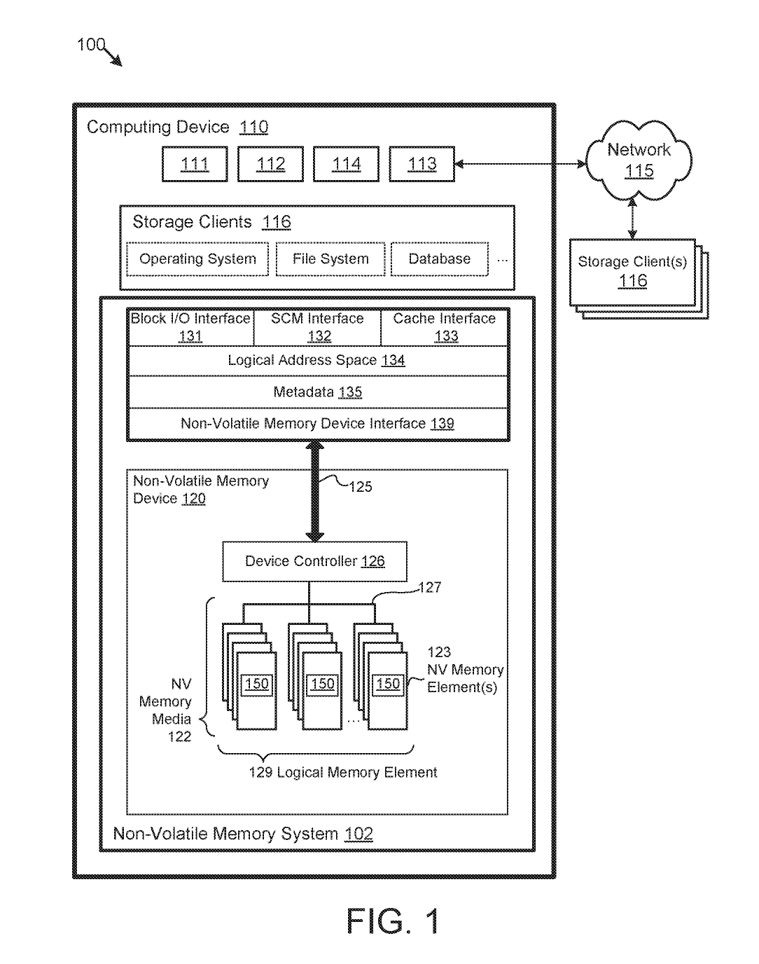

FIG. 1 is a block diagram of one embodiment of a system 100 comprising sense amplifiers 150 for a non-volatile memory device 120. The sense amplifiers 150 may be part of non-volatile memory elements 123, and may be in communication with a device controller 126 external to the non-volatile memory elements 123, a device driver, or the like. The sense amplifiers 150 may operate on a non-volatile memory system 102 of a computing device 110, which may comprise a processor 111, volatile memory 112, and a communication interface 113. The processor 111 may comprise one or more central processing units, one or more general-purpose processors, one or more application-specific processors, one or more virtual processors (e.g., the computing device 110 may be a virtual machine operating within a host), one or more processor cores, or the like. The communication interface 113 may comprise one or more network interfaces configured to communicatively couple the computing device 110 and/or non-volatile memory controller 124 to a communication network 115, such as an Internet Protocol network, a Storage Area Network, or the like.

The non-volatile memory device 120, in various embodiments, may be disposed in one or more different locations relative to the computing device 110. In one embodiment, the non-volatile memory device 120 comprises one or more non-volatile memory elements 123, such as semiconductor chips or packages or other integrated circuit devices disposed on one or more printed circuit boards, storage housings, and/or other mechanical and/or electrical support structures. For example, the non-volatile memory device 120 may comprise one or more direct inline memory module (DIMM) cards, one or more expansion cards and/or daughter cards, a solid-state-drive (SSD) or other hard drive device, and/or may have another memory and/or storage form factor. The non-volatile memory device 120 may be integrated with and/or mounted on a motherboard of the computing device 110, installed in a port and/or slot of the computing device 110, installed on a different computing device 110 and/or a dedicated storage appliance on the network 115, in communication with the computing device 110 over an external bus (e.g., an external hard drive), or the like.

The non-volatile memory device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the non-volatile memory device 120 may be disposed on a peripheral bus of the computing device 110, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the non-volatile memory device 120 may be disposed on a data network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The computing device 110 may further comprise a non-transitory, computer readable storage medium 114. The computer readable storage medium 114 may comprise executable instructions configured to cause the computing device 110 (e.g., processor 111) to perform steps of one or more of the methods disclosed herein.

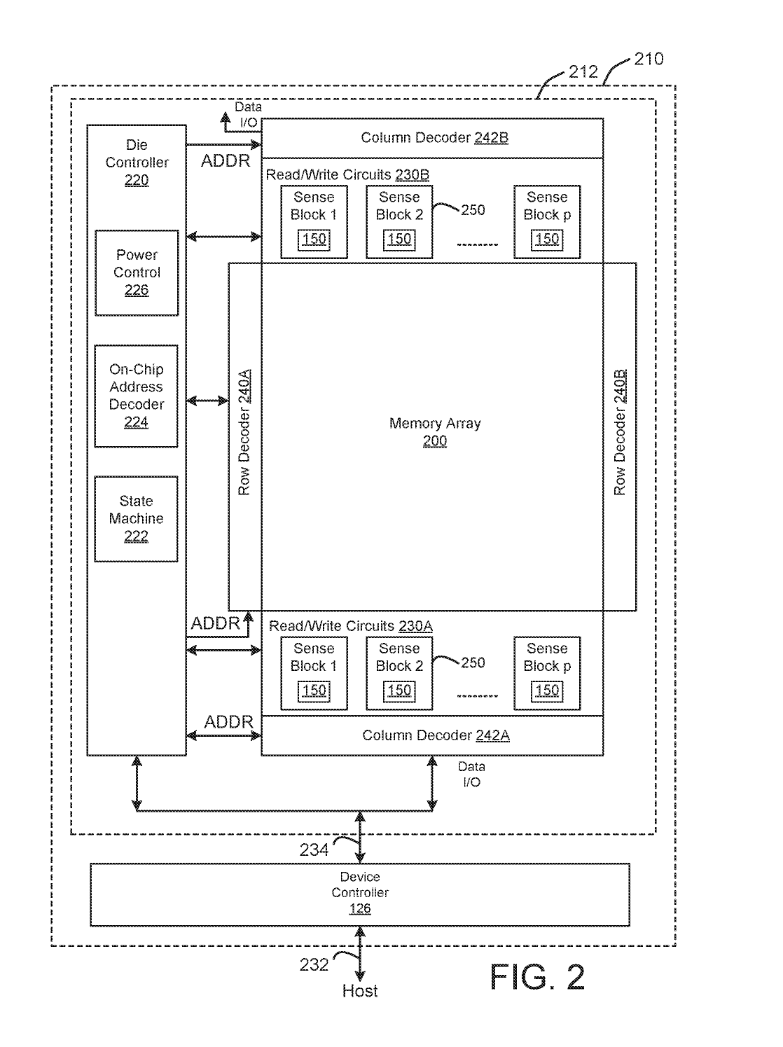

In the depicted embodiment, the non-volatile memory elements 123 include sense amplifiers 150. In certain embodiments, memory cells for the non-volatile memory elements 123 are coupled to bit lines, so that bit line currents during a sense operation correspond to memory cell states. A sense amplifier 150 may output a data result based on a bit line current. In one embodiment, a sense amplifier 150 may include a current to voltage conversion circuit that converts a current coupled to the sense amplifier to an analog voltage at a sense node. In a certain embodiment, a sense amplifier 150 may include a voltage to digital conversion circuit that converts the analog sense node voltage to a digital signal. The conversion from an analog voltage to a digital signal may be based on a voltage difference between the sense node and a comparison node during a strobe time. In a further embodiment, a sense amplifier 150 may include a bias circuit that biases the comparison node to a bias voltage other than a reference voltage at least during the strobe time. In various embodiments, biasing the comparison node may increase a range of bias voltages compatible with a sense amplifier 150, decrease die size for the sense amplifier 150, and/or decrease sense amplifier noise during the strobe time, relative to a sense amplifier with a grounded comparison node. Sense amplifiers 150 are described in further detail below with reference to FIGS. 2-13.

In one embodiment, the non-volatile memory device 120 is configured to receive storage requests from a device driver or other executable application via buses 125, 127, a device controller 126, or the like. The non-volatile memory device 120 may be further configured to transfer data to/from a device driver and/or storage clients 116 via the bus 125. Accordingly, the non-volatile memory device 120, in some embodiments, may comprise and/or be in communication with one or more direct memory access (DMA) modules, remote DMA modules, bus controllers, bridges, buffers, and so on to facilitate the transfer of storage requests and associated data. In another embodiment, the non-volatile memory device 120 may receive storage requests as an API call from a storage client 116, as an IO-CTL command, or the like.

According to various embodiments, a device controller 126 may manage one or more non-volatile memory devices 120 and/or non-volatile memory elements 123. The non-volatile memory device(s) 120 may comprise recording, memory, and/or storage devices, such as solid-state storage device(s) and/or semiconductor storage device(s) that are arranged and/or partitioned into a plurality of addressable media storage locations. As used herein, a media storage location refers to any physical unit of memory (e.g., any quantity of physical storage media on a non-volatile memory device 120). Memory units may include, but are not limited to: pages, memory divisions, blocks, sectors, collections or sets of physical storage locations (e.g., logical pages, logical blocks), or the like.

A device driver and/or the device controller 126, in certain embodiments, may present a logical address space 134 to the storage clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the non-volatile memory device 120 may maintain metadata 135, such as a logical to physical address mapping structure, to map logical addresses of the logical address space 134 to media storage locations on the non-volatile memory device(s) 120. A device driver may be configured to provide storage services to one or more storage clients 116. The storage clients 116 may include local storage clients 116 operating on the computing device 110 and/or remote, storage clients 116 accessible via the network 115 and/or network interface 113. The storage clients 116 may include, but are not limited to: operating systems, file systems, database applications, server applications, kernel-level processes, user-level processes, applications, and the like.

A device driver may be communicatively coupled to one or more non-volatile memory devices 120. The one or more non-volatile memory devices 120 may include different types of non-volatile memory devices including, but not limited to: solid-state storage devices, semiconductor storage devices, SAN storage resources, or the like. The one or more non-volatile memory devices 120 may comprise one or more respective device controllers 126 and non-volatile memory media 122. A device driver may provide access to the one or more non-volatile memory devices 120 via a traditional block I/O interface 131. Additionally, a device driver may provide access to enhanced functionality through the SCM interface 132. The metadata 135 may be used to manage and/or track data operations performed through any of the Block I/O interface 131, SCM interface 132, cache interface 133, or other, related interfaces.

The cache interface 133 may expose cache-specific features accessible via a device driver for the non-volatile memory device 120. Also, in some embodiments, the SCM interface 132 presented to the storage clients 116 provides access to data transformations implemented by the one or more non-volatile memory devices 120 and/or the one or more device controllers 126.

A device driver may present a logical address space 134 to the storage clients 116 through one or more interfaces. As discussed above, the logical address space 134 may comprise a plurality of logical addresses, each corresponding to respective media locations the on one or more non-volatile memory devices 120. A device driver may maintain metadata 135 comprising any-to-any mappings between logical addresses and media locations, or the like.

A device driver may further comprise and/or be in communication with a non-volatile memory device interface 139 configured to transfer data, commands, and/or queries to the one or more non-volatile memory devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The non-volatile memory device interface 139 may communicate with the one or more non-volatile memory devices 120 using input-output control (IO-CTL) command(s), IO-CTL command extension(s), remote direct memory access, or the like.

The communication interface 113 may comprise one or more network interfaces configured to communicatively couple the computing device 110 and/or the device controller 126 to a network 115 and/or to one or more remote, network-accessible storage clients 116. The storage clients 116 may include local storage clients 116 operating on the computing device 110 and/or remote, storage clients 116 accessible via the network 115 and/or the network interface 113. The device controller 126 is part of and/or in communication with one or more non-volatile memory devices 120. Although FIG. 1 depicts a single non-volatile memory device 120, the disclosure is not limited in this regard and could be adapted to incorporate any number of non-volatile memory devices 120.

The non-volatile memory device 120 may comprise one or more elements 123 of non-volatile memory media 122, which may include but is not limited to: ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more elements 123 of non-volatile memory media 122, in certain embodiments, comprise storage class memory (SCM).

While legacy technologies such as NAND flash may be block and/or page addressable, storage class memory, in one embodiment, is byte addressable. In further embodiments, storage class memory may be faster and/or have a longer life (e.g., endurance) than NAND flash; may have a lower cost, use less power, and/or have a higher storage density than DRAM; or offer one or more other benefits or improvements when compared to other technologies. For example, storage class memory may comprise one or more non-volatile memory elements 123 of ReRAM, Memristor memory, programmable metallization cell memory, phase-change memory, nano RAM, nanocrystal wire-based memory, silicon-oxide based sub-10 nanometer process memory, graphene memory, SONOS memory, PMC memory, CBRAM, MRAM, and/or variations thereof.

While the non-volatile memory media 122 is referred to herein as “memory media,” in various embodiments, the non-volatile memory media 122 may more generally comprise one or more non-volatile recording media capable of recording data, which may be referred to as a non-volatile memory medium, a non-volatile storage medium, or the like. Further, the non-volatile memory device 120, in various embodiments, may comprise a non-volatile recording device, a non-volatile memory device, a non-volatile storage device, or the like. Similarly, a non-volatile memory element 123, in various embodiments, may comprise a non-volatile recording element, a non-volatile memory element 123, a non-volatile storage element, or the like.

The non-volatile memory media 122 may comprise one or more non-volatile memory elements 123, which may include, but are not limited to: chips, packages, planes, die, or the like. A device controller 126, external to the one or more non-volatile memory elements 123, may be configured to manage data operations on the non-volatile memory media 122, and may comprise one or more processors, programmable processors (e.g., FPGAs), ASICs, micro-controllers, or the like. In some embodiments, the device controller 126 is configured to store data on and/or read data from the non-volatile memory media 122, to transfer data to/from the non-volatile memory device 120, and so on.

The device controller 126 may be communicatively coupled to the non-volatile memory media 122 by way of a bus 127. The bus 127 may comprise an I/O bus for communicating data to/from the non-volatile memory elements 123. The bus 127 may further comprise a control bus for communicating addressing and other command and control information to the non-volatile memory elements 123. In some embodiments, the bus 127 may communicatively couple the non-volatile memory elements 123 to the device controller 126 in parallel. This parallel access may allow the non-volatile memory elements 123 to be managed as a group, forming a logical memory element 129. The logical memory element may be partitioned into respective logical memory units (e.g., logical pages) and/or logical memory divisions (e.g., logical blocks). The logical memory units may be formed by logically combining physical memory units of each of the non-volatile memory elements 123.

The device controller 126 may comprise and/or be in communication with a device driver executing on the computing device 110. A device driver may provide storage services to the storage clients 116 via one or more interfaces 131, 132, and/or 133. In some embodiments, a device driver provides a block-device I/O interface 131 through which storage clients 116 perform block-level I/O operations. Alternatively, or in addition, a device driver may provide a storage class memory (SCM) interface 132, which may provide other storage services to the storage clients 116. In some embodiments, the SCM interface 132 may comprise extensions to the block device interface 131 (e.g., storage clients 116 may access the SCM interface 132 through extensions or additions to the block device interface 131). Alternatively, or in addition, the SCM interface 132 may be provided as a separate API, service, and/or library. A device driver may be further configured to provide a cache interface 133 for caching data using the non-volatile memory system 102.

A device driver may further comprise a non-volatile memory device interface 139 that is configured to transfer data, commands, and/or queries to the device controller 126 over a bus 125, as described above.

FIG. 2 illustrates an embodiment of a non-volatile storage device 210 that may include one or more memory die or chips 212. The non-volatile storage device 210 may be substantially similar to the non-volatile memory device 120 described with reference to FIG. 1. Memory die 212, in some embodiments, includes an array (two-dimensional or three dimensional) of memory cells 200, die controller 220, and read/write circuits 230A/230B. In one embodiment, access to the memory array 200 by the various peripheral circuits is implemented in a symmetric fashion, on opposite sides of the array, so that the densities of access lines and circuitry on each side are reduced by half. The read/write circuits 230A/230B, in a further embodiment, include multiple sense blocks 250 which allow a page of memory cells to be read or programmed in parallel.

The memory array 200, in various embodiments, is addressable by word lines via row decoders 240A/240B and by bit lines via column decoders 242A/242B. In some embodiments, a device controller 126 may be included in the same memory device 210 (e.g., a removable storage card or package) as the one or more memory die 212. Commands and data are transferred between the host and device controller 126 via lines 232 and between the device controller 126 and the one or more memory die 212 via lines 234. One implementation can include multiple chips 212.

Die controller 220, in one embodiment, cooperates with the read/write circuits 230A/230B to perform memory operations on the memory array 200. The die controller 220, in certain embodiments, includes a state machine 222, an on-chip address decoder 224, and a power control circuit 226.

The state machine 222, in one embodiment, provides chip-level control of memory operations. The on-chip address decoder 224 provides an address interface to convert between the address that is used by the host or a memory controller to the hardware address used by the decoders 240A, 240B, 242A, 242B. The power control circuit 226 controls the power and voltages supplied to the word lines and bit lines during memory operations. In one embodiment, power control circuit 226 includes one or more charge pumps that can create voltages larger than the supply voltage.

In one embodiment, the sense blocks 250 may include sense amplifiers 150, which may be substantially similar to the sense amplifiers 150 described above with reference to FIG. 1.

An individual sense block 250 may be partitioned into one or more core portions, referred to as sense modules or sense amplifiers 150, and a common portion, referred to as a managing circuit. In one embodiment, a separate sense amplifier 150 may be coupled to each bit line and one common managing circuit for a set of multiple (e.g., four or eight) sense amplifiers 150. Each of the sense amplifiers 150 in a group may communicate with the associated managing circuit via a data bus.

A sense amplifier 150 may determine or sense an electrical property (e.g., voltage, current) of a bit line for reading data. A sense block 250 or a sense amplifier 150 may also include one or more bit line latches to store data that has been read via a bit line, or data to be written to a bit line. A sense block 250 or a sense amplifier 150 may further include bias components that apply a bias voltage to the bit line for writing data. In one embodiment, the bias voltage may be based on data to be written via the bit line, the contents of the bit line latches, or the like.

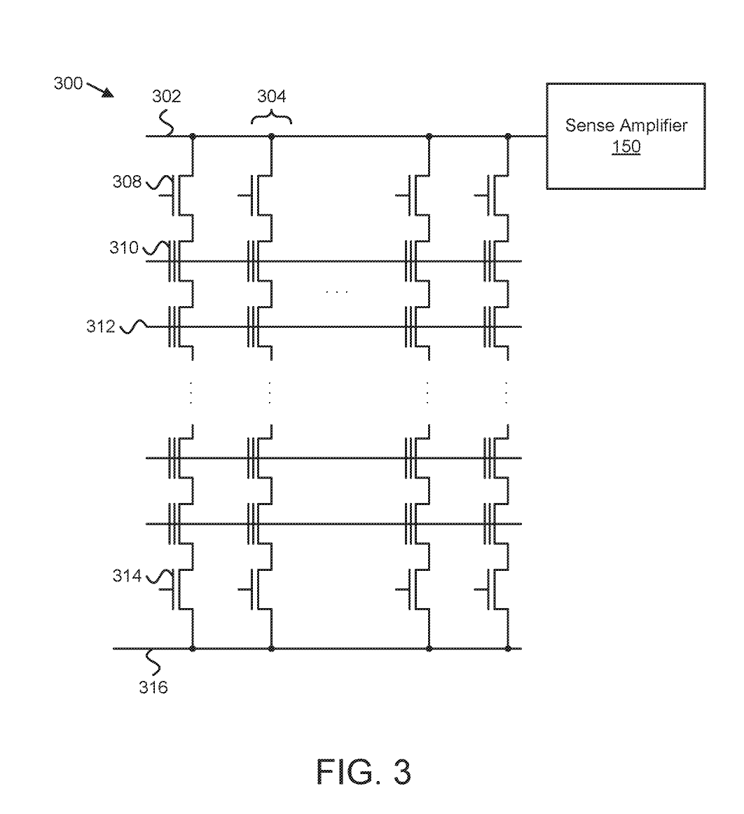

FIG. 3 depicts one embodiment of an apparatus 300 for accessing non-volatile memory. In the depicted embodiment, the apparatus 300 includes a bit line 302, one or more NAND strings 304, a sense amplifier 150, word lines 312, and a source line 316.

In various embodiments, a memory cell may be coupled between a source line 316 and a bit line 302. In certain embodiments, a “cell” may refer to a smallest or fundamental physical unit of memory, or storage, for an array 200, and may be referred to interchangeably as a “storage cell,” a “memory cell” or the like. For example, a cell may be a floating gate transistor for NAND flash memory, a memristor for resistive memory, or the like. Thus, in a further embodiment, an array 200 of cells may be a two-dimensional grid, a three-dimensional block, a group, or other similar set of cells where data can be physically stored, for short-term memory use, long-term storage use, or the like. In certain embodiments, a non-volatile memory element 123 may include further or peripheral components in addition to the array 200, such as word line drivers, sense amplifiers 150 for bit lines, latches to store data that is being read from or written to the array 200, and the like.

A physical or electrical property of a memory cell may be alterable to store data. For example, transistor-based memory cells (e.g., NAND) may store data based on an alterable threshold voltage for turning on the transistor. Similarly, resistive memory cells (e.g., PCM or MRAM) may store data based on an alterable resistance. A range of possible values for a cell's alterable physical property may be divided into states, corresponding to data values. With bias voltages applied to the cell at a source line 316, a word line 312, a bit line 302, and/or the like, the state of the cell may affect the voltage, current, or other electrical property of the bit line 302. The sense amplifier 150 may sense the affected electrical property (corresponding to the state of the cell), and may output a data result. In one embodiment, an electrical current that passes through a cell between a bit line 302 and a source line 316 may pass through a single cell. In the depicted embodiment, however, a chain of cells may be coupled in series between a source line 316 and a bit line 302, and an electrical current that passes through one cell may pass through other cells in the chain. However, the other cells may be controlled to be on (e.g., in a known, low-resistance state), so that the sensed electrical property of the bit line 302 corresponds to the state of one of the cells in the chain. A single cell or a cell in a chain may be equivalently referred to as coupled between a source line 316 and a bit line 302. Additionally, a cell may be referred to as coupled between a source line 316 and a bit line 302 whether the cell is directly connected to the source line 316 and the bit line 302, or coupled via other components such as select transistors 308, 314.

A source line 316 may be coupled to multiple cells. With reference to sensing data from one cell, however, a source line 316 may be referred to as a source node, and the cell may be referred to as coupled between a source node and a bit line 302.

In various embodiments, bit lines 302 may be coupled to memory cells in a variety of ways. For example, in the depicted embodiment, a bit line 302 is coupled to multiple NAND strings 304, where a NAND string 304 includes a plurality of storage cells connected in series, and where individual NAND strings 304 are selectable via select transistors 308, 314. In another embodiment, a bit line 302 may be coupled to a single NAND string 304. In a further embodiment, two-terminal cells may be coupled to bit lines 302 and word lines 312 (e.g., in a cross-point array where a word line 312 addresses a row of cells and a bit line 301 addresses a column of cells), and cells may or may not be coupled to a source line 316. Various ways of coupling memory cells to bit lines 302 will be clear in view of this disclosure. In certain embodiments, the cells may be coupled to the bit lines 302 such that electrical currents in the bit lines 302 during a sense operation correspond to memory cell states.

In the depicted embodiment, a NAND string 304 includes a plurality of floating gate transistors 310. In a floating gate transistor 310, a conductive “floating” gate is positioned over a channel region of a semiconductor substrate, between source and drain regions. A control gate is positioned over the floating gate. The floating gate is electrically isolated (e.g., by oxide layers) from the control gate and the substrate, and may store a charge. The charge on a floating gate may be increased (e.g., during programming) or decreased (e.g., during erasure) by Fowler-Nordheim tunneling, hot carrier injection, or the like. Because the floating gate is between the control gate and the substrate, the amount of charge on the floating gate may affect the “threshold voltage” Vt that is sufficient to turn the floating gate transistor 310 “on” (e.g., to create a conductive channel between source and drain regions) when applied to the control gate. Thus, the amount of charge on the floating gate, or, equivalently, the threshold voltage Vt for the floating gate transistor 310 may be manipulated to store data.

In one embodiment, in “single level cell” (SLC) NAND flash memory, a single read voltage threshold may be established for a floating gate transistor 310, so that the floating gate transistor 310 is in an erased state (e.g., storing a binary “1”) if the threshold voltage Vt for the cell is below the read voltage threshold, and in a programmed state (e.g., storing a binary “0”) if the threshold voltage Vt for the cell is above the read voltage threshold. In another embodiment, for “multi level cell” (MLC), “triple level cell” (TLC) NAND flash memory, or the like, a range of possible threshold voltages Vt for a floating gate transistor 310 may be divided into multiple states, so that the floating gate transistor 310 stores more than one bit of data. In general, in various embodiments, reading data from a floating gate transistor 310 may include determining which state the threshold voltage Vt of the floating gate transistor 310 is in, by applying a read voltage to the control gate and determining whether the floating gate transistor 310 conducts between source and drain terminals. Similarly, writing data to a floating gate transistor 310 may include applying program voltage pulses to the control gate, or applying erase voltage pulses to the substrate, to change the threshold voltage Vt of the floating gate transistor 310.

Although data is stored in floating gate transistors 310 in the depicted embodiment, data in another embodiment may be stored by varying certain physical properties of other types of electrical components. For example, data may be stored by varying the resistance of a component in ReRAM, the phase of a component in PCM, or the like. A component, such as a floating gate transistor 310, with a physical property that may be altered to store data may be referred to herein as a “storage cell,” a “memory cell” or the like. Thus, in the depicted embodiment, the memory array 200 of FIG. 2 may include multiple storage cells, comprising floating gate transistors 310 in NAND strings 304. In another embodiment, however, the memory array 200 of FIG. 2 may include multiple storage cells of another type.

In the depicted embodiment, a NAND string 304 includes a series of floating gate transistors 310, daisy chained source-to-drain. A source select transistor 314 couples the source end of the NAND string 304 to a source line 316, and a drain select transistor 308 couples the drain end of the NAND string 304 to a bit line 302. In a certain embodiment, the source line 316 may be maintained at a source voltage V_{SS} (e.g., 0 V, or ground), and the bit line 302 voltage may be manipulated by the sense amplifier 150 to read or write data. The source line 316 may be referred to as a cell source line, to distinguish the source line 316 that is coupled to the cells from other connections to 0 V or ground. Word lines 312 may couple control gates of corresponding floating gate transistors 310 across multiple NAND strings 304. Thus, a full row of floating gate transistors 310 (e.g., a page of data for SLC NAND, or multiple pages of data for MLC or TLC NAND) may be addressed via a single word line 312, with individual bits read or programmed via columns or bit lines 302. In the depicted embodiment, a 3-dimensional NAND arrangement is shown, in which multiple NAND strings 304 are coupled to one bit line 302, and a bit stored by a floating gate transistor 310 is physically addressed by row (e.g., word line 312), column (e.g., bit line 302), and string 304, (e.g., selected via select transistors 308, 314). In another embodiment, in a 2-dimensional NAND arrangement, each NAND string 304 is coupled to a single bit line 302, and a bit stored by a floating gate transistor 310 is physically addressed by row (e.g., word line 312), and column (e.g., bit line 302), without separately addressing a string 304.

In the depicted embodiment, as described above, reading data from a floating gate transistor 310 may include applying a read voltage to the control gate of the floating gate transistor 310 and determining whether the floating gate transistor 310 conducts between source and drain terminals. When reading or writing data for a floating gate transistor 310, the term “selected” may be used herein to refer to the floating gate transistor 310 in question, the NAND string 304 that includes the selected floating gate transistor 310, the word line 312 coupled to the selected floating gate transistor 310, and the like. Conversely, the term “unselected” may be used herein to refer to floating gate transistors 310 other than the selected floating gate transistor 310, NAND strings 304 other than the selected NAND string 304, word lines 312 other than the selected word line 312, and the like.

In one embodiment, to read data from a selected floating gate transistor 310, the sense amplifier 150 precharges or biases the selected bit line 302. The source select transistor 314 and the drain select transistor 308 for a selected string 304 may be turned on (e.g., a voltage may be applied to control gates so that the select transistors 308, 314 are in a conducting state). Select transistors 308, 314 for unselected strings 304 may be turned off (e.g., control gates may be at 0 V). A voltage sufficient to fully turn on the unselected floating gate transistors 310 is applied via the unselected word lines 312. A read voltage is applied to the selected word line 312. If the threshold voltage Vt for the selected floating gate transistor 310 is below the applied read voltage (e.g., the storage cell is in an erased state for SLC NAND), then the selected floating gate transistor 310 conducts, and a current flows between the bit line 302 and the source line 316. Conversely, if the threshold voltage Vt for the selected floating gate transistor 310 is above the applied read voltage (e.g., the storage cell is in a programmed state for SLC NAND), then the selected floating gate transistor 310 does not conduct, and current does not flow between the bit line 302 and the source line 316 (or, a lower, or minimal current flows). Applying a single read voltage may be sufficient to distinguish between programmed and erased states for SLC NAND. Additional read voltages may be applied to distinguish between multiple states for MLC NAND, TLC NAND, or the like. The sense amplifier 150 may sense an electrical property of the bit line 302, such as a bit line voltage, a rate of change in a bit line voltage, a bit line current, or the like, to determine the state of the cell.

In a certain embodiment, for writing as for reading, a string 304 may be selected by applying appropriate voltages to select transistors 308, 314, and unselected floating gate transistors 310 may be fully turned on by applying a sufficient voltage to unselected word lines 312. One or more program voltage pulses may be applied to the control gate for the selected floating gate transistor 310, via the selected word line 312, to change the threshold voltage Vt for the selected floating gate transistor 310. Changes to the threshold voltage Vt for the selected floating gate transistor 310 may be verified in a process similar to reading, by applying one or more program verify voltages to the selected floating gate transistor 310, and sensing whether the selected floating gate transistor 310 conducts.

In various embodiments, the degree to which a threshold voltage Vt for a selected floating gate transistor 310 changes in response to a programming pulse depends on the size of voltage between the control gate and the drain. In one embodiment, to inhibit a cell from being programmed, a sense amplifier 150 may apply a high inhibit voltage to the drain of the selected floating gate transistor 310, via the bit line 302. In another embodiment, for fast programming, or for programming to a high threshold voltage Vt, a sense amplifier 150 may apply a low or zero voltage to the drain of the selected floating gate transistor 310, via the bit line 302. In certain embodiments, a sense amplifier 150 may apply a bias voltage to the drain of the selected floating gate transistor 310, via the bit line 302. In some embodiments, a small, but non-zero bias voltage may reduce program disturb phenomena that affect floating gate transistors 310 in nearby or adjacent unselected NAND strings 304. In further embodiments, a bias voltage at some level between zero volts and the inhibit voltage may effectively reduce the size of the program voltage pulses, by reducing the voltage difference between the control gate and the drain of the selected floating gate transistor 310, to slow programming, or to program the selected floating gate transistor 310 into a state with an intermediate threshold voltage Vt.

Read and program operations are described above in the context of reading or writing data to a single floating gate transistor 310. However, in various embodiments, a word line 312 may couple control gates for a row of floating gate transistors 310 that spans multiple NAND strings 304 and bit lines 302. Thus, a read voltage or a program voltage pulse may be applied to a word line 312, and multiple bits of data may be communicated via multiple bit lines 302, to read data from or write data to floating gate transistors 310 coupled to the selected word line 312. In some embodiments, a subset of floating gate transistors 310 coupled to the selected word line 312 may be unselected. For example, in one embodiment, strings 304 may still be individually selected as described above if multiple strings 304 are coupled to one bit line 302. In certain embodiments, a partial row may be programmed by selecting only even bit lines 302, only odd bit lines 302, or the like. However, in general, in various embodiments, data is programmed to or read from multiple floating gate transistors 310 in a row using one word line 312 and multiple bit lines 302.

To read a page of data, a read voltage may be applied to a word line 312, and sense amplifiers 150 may determine which bit lines 302 are discharged through floating gate transistors 310 coupled to the word line 312. In certain embodiments, where the range of possible threshold voltages Vt for a floating gate transistor 310 is divided into more than two states, multiple pages of data may be read from the same row of floating gate transistors 310 by applying successive read voltages to the word line 312.

Similarly, to program a page of data, one or more program pulses may be applied to a word line 312 and sense amplifiers 150 may apply different voltages to different bit lines 302 to program or inhibit floating gate transistors 310 coupled to the word line 312. In one embodiment, multiple pages of data may be programmed to the same row of floating gate transistors 310 by applying inhibit voltages to different bit lines 302 at different times, or by applying different bias voltages to different bit lines 302 to affect programming speeds, so that different floating gate transistors 310 are programmed into different states.

In certain embodiments, the range of possible threshold voltages Vt for a floating gate transistor 310 may include negative voltages. In certain embodiments, a range of threshold voltages Vt that includes negative voltages may be larger than a range that does not include negative voltages, and may be divided into a larger number of stages, to store more bits per cell, or may be divided into wider, more reliable states. A floating gate transistor 310 in a negative voltage state may conduct when a read voltage of 0 V is applied to the control gate, and may turn off when a negative voltage is below a threshold. Applying a negative read voltage may use area of a memory die 212 for a negative voltage source. Thus, rather than applying a negative voltage to the control gate or word line 312, the word line 312 may be biased at 0 V, while the source line 316 or source node and the bit line 302 are biased to higher voltages, so that the control gate for the floating gate transistor 310 is negative relative to the source and drain terminals.

To produce a current (for states when the floating gate transistor 310 conducts), the bit line 302 may be biased to a higher voltage than the source line 316, so that a current flows from the bit line 302 to the source node. Alternatively, the bit line 302 may be biased to a lower voltage than the source line 316, so that a current flows to the bit line 302 from the source node. With 0 V applied to the word line 312, the read voltage is effectively a negative voltage equal in magnitude to whichever is smaller of the bit line bias voltage or the source line bias voltage. In certain embodiments, a bias voltage for a bit line 302 may be subject to an upper limit for the sense amplifier 150, so biasing the source line 316 higher than the bit line 302 may provide deeper effective read voltages than biasing the source line 316 lower than the bit line 302.

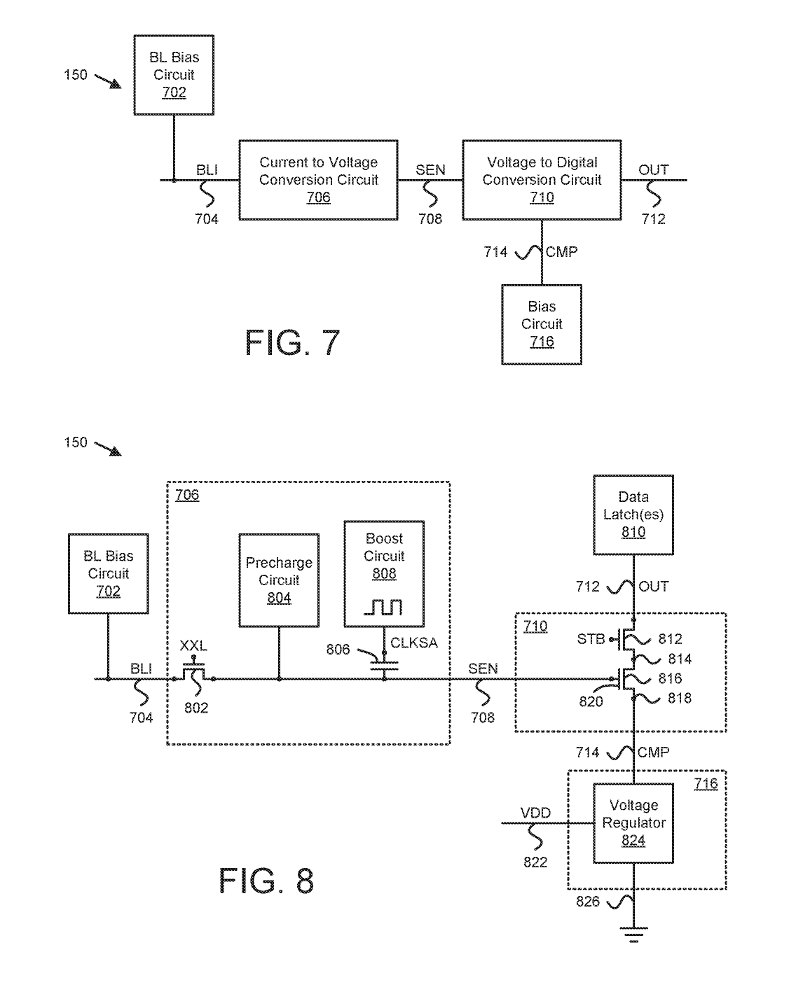

In the depicted embodiment, the floating gate transistors 310 are NAND flash storage cells. However, in various embodiments, word lines 312 and bit lines 302 for other types of storage cells including resistive storage cells, magnetic storage cells, phase change storage cells, or the like, may be similarly arranged so that a sense amplifier 150 senses an electrical property of a bit line 302 for reading data and applies a bias voltage to a bit line 302 for writing data. Sense amplifiers 150 are described in further detail below with reference to FIGS. 7 and 8.

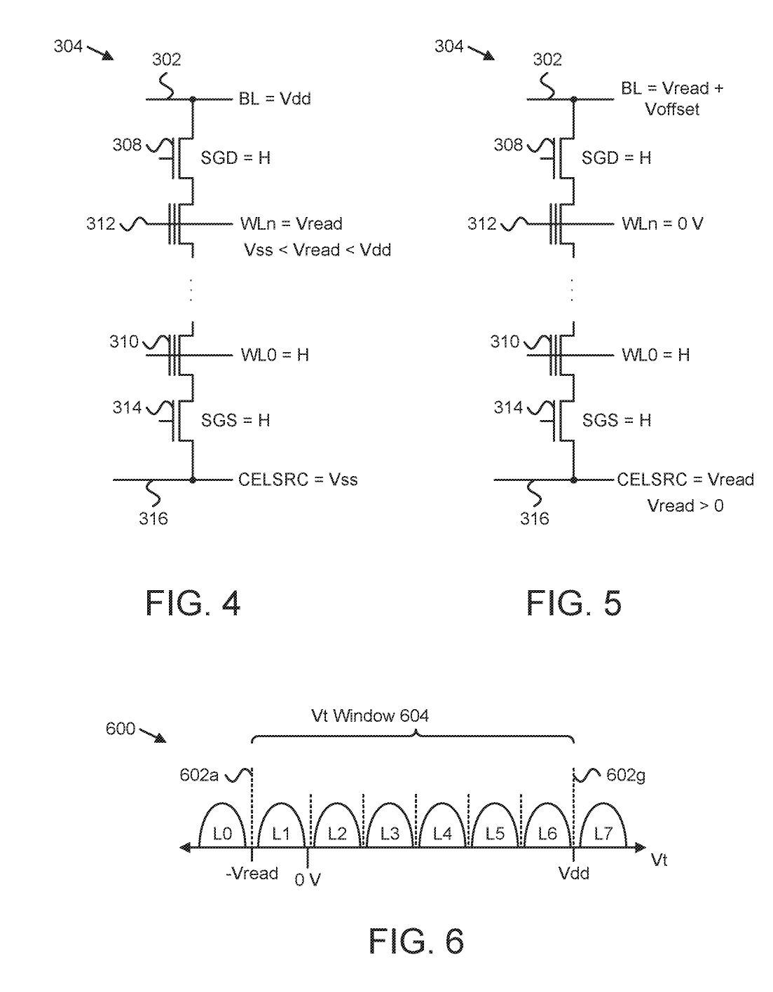

FIG. 4 depicts one embodiment of bias voltages for a NAND string 304 during a sense operation. The NAND string 304, in the depicted embodiment, may be substantially similar to the NAND string 304 described above with reference to FIG. 3, including a drain select transistor 308, a series of daisy-chained floating gate transistors 310 addressed by word lines 312, and a source select transistor 314, coupled between a bit line 302 and a cell source line 316, substantially as described above. The voltages depicted in FIGS. 4-6 are provided as examples, and are intended as illustrative and not limiting. In another embodiment, another set of bias voltages may be applied during a sense operation.

A sense operation, in various embodiments, may be any operation in which the state of a cell is partially or fully sensed, detected, or determined. For example, in one embodiment, a sense operation may include detecting the state of a cell. In another embodiment, a sense operation may include comparing the state of the cell to a threshold, or determining that the state of the cell is in a group of states (or is not in a group of states). For example, where a cell is a floating gate transistor 310 that stores data using an alterable threshold voltage Vt, a sense operation may include determining the threshold voltage Vt, or may include determining whether the threshold voltage Vt is above or below a threshold. Bias voltage for sense operations may be applied by read/write circuits 230, row decoders 240, a die controller 220, a state machine 222, a sense block 250, a sense amplifier 150 or the like, as depicted in FIG. 2.

Where a sense operation compares the state of a cell to a threshold, determining the state of the cell may involve a series of sense operations. For example, for a cell with eight states, a first sense operation may determine whether the cell is in one of the first four states or one of the last four states, a second sense operation may determine that the cell is in one of two states, and a third sense operation may determine the state of the cell. Sense operations may be performed in response to read commands from a client, where data read from a cell is then returned to the client, may be performed internally without returning data (e.g., to read data that as part of a copy, move, or garbage collection operation), or may be performed during program, erase, or write operations to verify whether a cell has been successfully programmed or erased into a target state. Various types of sense operations and various further operations that include sense operations will be clear in view of this disclosure.

In the depicted embodiment, the sense operation determines whether the threshold voltage Vt for a selected cell on the nth word line WLn is above or below a positive read threshold voltage Vread. In the depicted embodiment, the cell source line 316 is biased to a low supply voltage or source voltage Vss (e.g., 0 volts, or ground), and the bit line is biased to a positive supply voltage Vdd. Control gate voltages SGD for the drain select transistor 308, SGS for the source select transistor 314, and for unselected floating gate transistors 310 (e.g., the cell on the 0th word line WL0) are set to a “high” voltage represented by the letter H, such as a positive supply voltage or another voltage sufficient to fully turn on the transistors 308, 310, 314. Thus, in the depicted embodiment, a current will flow from the bit line 302 to the cell source line 316 if the selected cell conducts. A read voltage Vread is applied to the control gate of the selected cell. In the depicted embodiment, the read voltage Vread may be between the source voltage Vss for the source line 316 and the positive supply voltage Vdd for the bit line 302. If the applied read voltage Vread is above the threshold voltage Vt for the selected cell, then the cell conducts, and a bit line current may be detected by a sense amplifier 150. Conversely, if the applied read voltage Vread is below the threshold voltage Vt for the selected cell, then the cell does not conduct, and the bit line current may be zero (or may be a minimal leakage current).

In the depicted embodiment, the bias voltage for the bit line 302 is depicted at a positive supply voltage Vdd. In another embodiment, however, the bias voltage for the bit line 302 may be applied based on the applied read voltage Vread. In order for a current to flow from the bit line 302 to the source line 316 if the applied read voltage Vread is sufficient to turn the selected cell on, the bias voltage for the bit line 302 may be set to a voltage that is higher than the bias voltage for the source line 316, and higher than the applied read voltage Vread. For example, in one embodiment, the bit line bias voltage may be Vread plus an offset voltage Voffset, where the offset voltage Voffset is selected based on a desired bit line current. For example, a higher offset may increase currents for easier detection by a sense amplifier 150, but may increase power use or disturb effects on nearby NAND strings 304, while a lower offset may decrease power use and disturb effects but with lower bit line currents that are more difficult to detect.

In certain embodiments, using the depicted bias voltages, a sense amplifier 150 may determine whether the threshold voltage Vt for the selected cell is above or below a read voltage threshold, where the read voltage threshold may be anywhere from the low supply voltage Vss applied to the cell source line 316, to the high supply voltage Vdd applied to the bit line 302. However, the window of possible read voltages Vread may be limited by available supply voltages. For example, if a memory die 212 does not provide a negative voltage source, the applied read voltage Vread may not be below Vss or ground. However, FIG. 5 depicts sensing whether the threshold voltage Vt for the selected cell is above or below a negative read voltage threshold

FIG. 5 depicts another embodiment of bias voltages for a NAND string 304 during a sense operation. The NAND string 304, in the depicted embodiment, may be substantially similar to the NAND string 304 described above with reference to FIGS. 3 and 4, including a drain select transistor 308, a series of daisy-chained floating gate transistors 310 addressed by word lines 312, and, a source select transistor 314, coupled between a bit line 302 and a cell source line 316, substantially as described above. As in FIG. 4, the bias voltages depicted in FIG. 5 are provided as example of bias voltages during a sense operation, and are intended as illustrative and not limiting. In another embodiment, another set of bias voltages may be applied during a sense operation.

In the depicted embodiment, the sense operation determines whether the threshold voltage Vt for a selected cell on the nth word line WLn is above or below a negative read threshold voltage. In the depicted embodiment, as in FIG. 4, control gate voltages SGD for the drain select transistor 308, SGS for the source select transistor 314, and for unselected floating gate transistors 310 (e.g., the cell on the 0th word line WL0) are set to a “high” voltage represented by the letter H, such as a positive supply voltage or another voltage sufficient to fully turn on the transistors 308, 310, 314. Thus, in the depicted embodiment, a current will flow from the bit line 302 to the cell source line 316 if the selected cell conducts. However, in the depicted embodiment, the voltage applied to the control gate of the selected cell is 0 volts, while the bit line 302 and the cell source line 316 are biased to positive voltages.

In the depicted embodiment, the bit line 302 is biased to a higher bias voltage than the cell source line 316, so that current flow if the cell conducts is from the bit line 302 to the source line 316 (e.g., with the current flowing out from a sense amplifier 150 coupled to the bit line 302, in the same direction as current flow in FIG. 4). In another embodiment, the bit line 302 may be biased to a lower voltage than the cell source line 316, so that current flow if the cell conducts is from the source line 316 to the bit line 302 (e.g., with the current flowing into a sense amplifier 150 coupled to the bit line 302, in the opposite direction to current flow in FIG. 4). However, in certain embodiments, accommodating current flow in one direction for positive threshold voltage sensing (as in FIG. 4) and in the opposite direction for negative threshold voltage sensing may complicate sense amplifier design, resulting in larger sense amplifiers using more die area.

In the depicted embodiment, the cell source line 316 is biased to a positive voltage Vread and the bit line 302 is biased slightly higher, to Vread+Voffset. The selected cell on the nth word line WLn may turn on if the gate-to-source voltage for the cell is above a threshold voltage Vt for the cell. Because the gate-to-source voltage is −Vread, the depicted set of bias voltages will result in a bit line current if the threshold voltage Vt for the selected cell is less than −Vread volts, and in no bit line current (or a minimal leakage current) if the threshold voltage Vt for the selected cell is above −Vread volts. Thus, biasing the cell source line 316 to a positive voltage Vread while holding the control gate of the selected cell at 0 volts provides sensing for negative threshold voltages Vt.

Additionally, increasing the bias voltage Vread at the cell source line 316 increases the extent of negative threshold voltages Vt that can be sensed for the selected cell. However, in certain embodiments, providing a current from the bit line 302 to the cell source line 316 may involve biasing the bit line 302 to a higher voltage than the cell source line 316, which may in turn call for even higher bias voltages internally within the sense amplifier 150. Thus, in certain embodiments, the cell source line bias voltage, and the extent of negative threshold voltage sensing, may be limited by available voltage within the sense amplifier 150. In certain embodiments, however, biasing a comparison node of a sense amplifier 150, as described below with regard to FIGS. 7 and 8, may increase a range of available bias voltages for a cell source line 316, thus increasing the range of negative threshold voltages Vt that can be sensed for a selected cell.

FIG. 6 is a graph 600 depicting a distribution of threshold voltages for cells of a non-volatile memory device, in one embodiment. In the depicted embodiment, the range of possible threshold voltages Vt for a NAND flash cell is divided into eight subranges or states L0-L7 by read voltage thresholds 602a-g, represented by dashed lines. In another embodiment, a range of possible threshold voltages Vt for a NAND flash cell may be divided into more or fewer than eight states. In the depicted embodiment, cells are erased into the lowest state L0, and may be programmed into higher states L1-L7. Programming or erasing a cell may include applying program or erase voltage pulses until the threshold voltage Vt satisfies a write verify condition (e.g., satisfies a minimum and/or maximum threshold). To prevent errors that may occur when the threshold voltage Vt for a cell drifts from one state into another state, the verify conditions may be selected so that fewer cells have threshold voltages Vt near the read voltage thresholds 602a-g that define the states, and more cells have threshold voltages Vt further away from the read voltage thresholds 602a-g, resulting in a multiple-peaked voltage distribution, as depicted in the graph 600. (An idealized distribution is depicted for the sake of simplicity; an actual distribution may have asymmetric or overlapping peaks due to drift, charge leakage, or the like.)

In the depicted embodiment, the eight available states L0-L7 are defined by seven read voltage thresholds 602a-g. A sense operation may determine whether the threshold voltage Vt for a cell is above or below one of the read voltage thresholds 602. For a positive read voltage threshold 602, between 0 V and a positive supply voltage Vdd, a sense operation may be performed as described above with reference to FIG. 4, by setting the control gate voltage for a selected cell to the voltage threshold, with the bit line 302 biased high and the source line 316 biased low. For a negative read voltage threshold 602, below 0 V, a sense operation may be performed as described above with reference to FIG. 5, by setting the control gate voltage for a selected cell to 0 V, with the source line 316 biased to a positive read voltage Vread, and the bit line 302 biased higher than Vread.

Thus, the lowest read voltage threshold 602a in the depicted embodiment is determined by the available Vread voltage for negative threshold voltage sensing in FIG. 5, and the highest read voltage threshold 602g in the depicted embodiment is determined by the supply voltage Vdd in FIG. 4. A Vt window 604, in various embodiments, may be a range from the lowest read voltage threshold 602a to the highest read voltage threshold 602g. Thus, in the depicted embodiment, the Vt window 604 extends from −Vread (referring to the Vread used for negative threshold voltage sensing in FIG. 5) to Vdd (referring to the positive supply voltage in FIG. 4).

The erased state L0 includes cells with threshold voltages Vt below the lowest read voltage threshold 602a, and the highest programmed state L7 includes cells with threshold voltages Vt above the highest read voltage threshold 602g, but the remaining states L1-L6 include cells with threshold voltages in the Vt window 604. Accordingly, in various embodiments, increasing the size of the Vt window 604 may provide higher-density storage, with more states per cell, or more reliable storage with wider states less prone to drift and disturb errors, while decreasing the size of the Vt window 604 may decrease the storage density or reliability. However, as described above with regard to FIG. 5, the Vread voltage applied to the cell source line 316 for negative threshold voltage sensing may be limited in order to provide a detectable current from the sense amplifier 150 to the bit line 302 to the source line 316 without exceeding internal voltage limitations of the sense amplifier. Thus, in various embodiments, the size of the Vt window 604 may be affected by the design of the sense amplifier 150.

In another embodiment, cells other than flash memory cells may store data using an alterable physical or electrical property other than a threshold voltage Vt. Memory cells in various embodiments may similarly be coupled to bit lines, and biases (e.g., voltage or current biases) may be applied to bit lines, word lines, source lines, or the like, so that the bit line current during a sense operation, for a bit line coupled to a cell, corresponds to or is affected by the state of the cell. A sense amplifier 150 may similarly be coupled to a bit line to output a data result, digital signal, or logic level based on the bit line current. The range of possible values for the alterable physical or electrical property may similarly be divided into states by thresholds similar to the read voltage thresholds 602, and a window between the lowest and highest thresholds, similar to the Vt window 604 may affect the density or reliability of a memory device. In various embodiments, such a window may be limited by a range of available biases for bit lines, word lines, source lines, or the like, and may be affected by the design of the sense amplifier 150.

FIG. 7 is a schematic block diagram illustrating one embodiment of a sense amplifier 150. The sense amplifier 150, in the depicted embodiment, may be substantially similar to the sense amplifier 150 described above with reference to previous figures. In the depicted embodiment, the sense amplifier includes a current to voltage conversion circuit 706, a voltage to digital conversion circuit 710, and a bias circuit 716.

In general, in various embodiments, the sense amplifier 150 may convert a current coupled to the sense amplifier 150 to a digital signal. In one embodiment, the current coupled to the sense amplifier 150 may be a bit line current corresponding to the state of a memory cell, and the digital signal output by the sense amplifier 150 may be a data result such as a binary zero or one, based on the bit line current. In another embodiment, a sense amplifier 150 may be coupled to an analog current other that a bit line current, or may be used with components other than memory cells, but may similarly output a digital signal based on the analog current.

The sense amplifier 150 may sense a bit line current to determine a state of a memory cell. For example, for resistive memory, a bit line current may be low if the cell is in a high resistance state, and may be high if the cell is in a low resistance state. For NAND memory, a bit line current may be high if bias voltages applied to the bit line 302, the source node, and the control gate of a cell place the cell in a conducting state, and may be lower if bias voltages do not place the cell in a conducting state. The sense amplifier 150 may sense bit line currents for different bias voltages to determine a state of the cell (corresponding to a threshold voltage sufficient to turn the cell on), and to output a digital signal, result, or data value. A plurality of sense amplifiers 150, in certain embodiments, may be coupled to a plurality of bit lines, in further embodiments, and may output data results such as a byte of data stored by eight cells, a page of data stored by a row of cells, or the like, based on the bit line currents.

The term “digital,” as used herein, may refer to any voltage, current, or other signal that is discretized, or confined to a finite number of logic levels representing data. For example, in one embodiment, a high logic level may represent a binary one, while a low logic level represents a binary zero. In another embodiment, four different logic levels may represent four different two-bit data values, eight logic levels may represent eight different three-bit data values, or the like. A logic level may be a value or an allowed band of values for the voltage, current, or other discretized signal. The term “analog,” by contrast, may be used herein to refer to any voltage current, or other signal that is not digital, or is not confined to a finite number of logic levels.

In certain embodiments, whether a signal is digital or analog may depend on the existence of defined logic levels. For example, an analog signal may be interpreted as a digital signal by defining logic levels that determine whether the signal represents a 0 or a 1 at any given time. (However, in the absence of a gap between allowed logic levels, such a signal may not be reliable for representing data, because a small amount of noise may change the represented data value). Conversely, a digital signal may resemble an analog signal during transitions between logic levels, or due to noise, voltage drift or the like. However, in certain embodiments, the term “digital” may more specifically refer to voltages, currents, or other signals that are directly usable as logic inputs by electronic components of a device, such as logic gates, latches, or the like of a memory die 212. Conversely, the term “analog” may refer to voltages, currents, or other signals that are not directly usable as logic inputs by other electronic components of a device, even if the voltages, currents, or other signals do in some sense represent or correspond to a data value.

In certain embodiments, bit line currents during a sense operation may be low-power or low-amplitude analog signals. For example, bit line currents when a cell conducts may be small due to resistance through a long NAND string, and some amount of current may also flow when a cell does not conduct, due to self-capacitance of long bit lines, parasitic capacitance between a bit line and other components, or the like. In various embodiments, a sense amplifier 150 may output a digital signal based on the analog bit line current, and the digital output of the sense amplifier may be stored in latches, transmitted over a bus to a device controller or a host, or the like.

In the depicted embodiment, the sense amplifier 150 includes a bit line bias circuit 702. In certain embodiments, a bit line bias circuit 702 may be configured to couple a bias voltage to a bit line 302, as described above with reference to FIGS. 3-5. In various embodiments, a bit line bias circuit 702 may include or be coupled to one or more voltage supplies that provide bias voltages. In certain embodiments, a bit line bias circuit 702 may include one or more level shifters, voltage regulators, or the like, that produce a bit line bias voltage based on a supply voltage. In further embodiments, a bit line bias circuit 702 may include one or more switching components such as transistors, transfer gates, or the like, for coupling or decoupling bias voltages to or from the bit line 302. In a certain embodiment, a transistor controlled an analog signal may act as a voltage clamp to bias the bit line 302 (via the BLI node 704) to a bias voltage. Further switching transistors may couple supply voltages to an analog-controlled voltage clamp transistor, and in certain embodiments, different supply voltages may be coupled to a voltage clamp transistor at different times to provide different bit line bias voltages. Various further was of biasing a bit line will be clear in view of this disclosure.

In another embodiment, a sense amplifier 150 may not include a bit line bias circuit 702. In one embodiment, components for biasing a bit line 302 may be disposed outside of a sense amplifier 150. In another embodiment, a bit line bias circuit 702 may not be a discrete component of a sense amplifier 150, but may share components with other portions of a sense amplifier 150. For example, in one embodiment, the current to voltage conversion circuit 706 may include components for providing a bit line bias voltage.

The current to voltage conversion circuit 706, in the depicted embodiment, is configured to convert a current coupled to the sense amplifier 150 to an analog voltage at a sense node 708. In the depicted embodiment, the current may be coupled to the sense amplifier 150 at the BLI node 704. For example, a bit line 302 may be coupled to the BLI node 704 and biased by the bit line bias circuit 702. The coupled current may be zero or low if a cell coupled to the bit line does not conduct (given the applied bias voltages) or is in a high resistance state, or may be higher if the cell conducts, or is in a low resistance state. For the bias voltages depicted in FIGS. 4 and 5, the current coupled to the sense amplifier 150 may be a current out of the sense amplifier 150. In another embodiment with different biases, however, a current coupled to a sense amplifier 150 may be a current into the sense amplifier 150.

The sense node (SEN) 708, in certain embodiments, may be a node that is coupled to or shared by both the current to voltage conversion circuit 706, and to the voltage to digital conversion circuit 710. In general, in various embodiments, the current to voltage conversion circuit 706 converts the current at the BLI node 704 to an analog voltage at the sense node 708, and the voltage to digital conversion circuit 710 converts the analog voltage at the sense node 708 to a digital signal or data value.

In various embodiments, the current to voltage conversion circuit 706 may convert the current coupled to the sense amplifier 150 to an analog voltage at a sense node 708 in various ways. For example, in one embodiment, the current to voltage conversion circuit 706 may include a capacitor that charges to a higher voltage or discharges to a lower voltage based on the current at the BLI node 704. In another embodiment, the current to voltage conversion circuit 706 may include a resistor (so that the output analog voltage is a voltage drop across the resistor based on the input current), a bipolar junction transistor controlled by the input current, or the like. Various other or further ways of converting a current to an analog voltage, and further components for converting a current to an analog voltage, will be clear in view of this disclosure.

The voltage to digital conversion circuit 710, in the depicted embodiment, is configured to convert the analog voltage at the sense node 708, produced by the current to voltage conversion circuit 706, to a digital signal. In a certain embodiment the digital signal may be a binary data value, such as a zero or one. For example, the digital signal may be a voltage at a logic level that corresponds to a zero or one. The voltage to digital conversion circuit 710 may produce the digital signal at an output node (OUT) 712, from which the digital result may be latched into a buffer, transmitted to other logic components, or the like.

In certain embodiments, the voltage to digital conversion circuit 710 may convert the analog voltage at the sense node 708 to a digital signal based on based on a voltage difference between the sense node 708 and a comparison node (CMP) 714 during a strobe time. For example, in one embodiment, the voltage to digital conversion circuit 710 may output a zero if the voltage at the sense node 708, minus the voltage at the comparison node 714 is greater than a threshold, and a one otherwise. In another embodiment, the voltage to digital conversion circuit 710 may output a zero if the voltage at the sense node 708, minus the voltage at the comparison node 714 is greater than or equal to a threshold, and a one otherwise. In a certain embodiment, the voltage to digital conversion circuit 710 may output a one if the voltage at the sense node 708, minus the voltage at the comparison node 714 is greater than a threshold, and a zero otherwise. In another embodiment, the voltage to digital conversion circuit 710 may output a one if the voltage at the sense node 708, minus the voltage at the comparison node 714 is greater or equal to a threshold, and a zero otherwise.

In one embodiment, a threshold for the voltage to digital conversion circuit 710 may be an offset from the voltage at the comparison node 714, so that the digital signal at the output node 712 flips between one and zero when the voltage at the sense node 708 is offset above (or below) the voltage at the comparison node 714 by a certain amount. In another embodiment, a threshold for the voltage to digital conversion circuit 710 may be at the voltage of the comparison node 714, so that the digital signal at the output node 712 flips between one and zero when the voltage at the sense node 708 is at the comparison node voltage.

In certain embodiments, a strobe time may refer to a time period during which the voltage at the output node 712 depends on the voltage difference between the sense node 708 and the comparison node 714. In further embodiments, the output node 712 may be precharged to a high voltage (e.g., representing a binary one), discharged to a low voltage (e.g., representing a binary zero), floating, or otherwise uncontrolled by the voltage to digital conversion circuit 710 at times other than during the strobe time. For example, in one embodiment, the voltage to digital conversion circuit 710 may include a comparison component that compares the voltage at the sense node 708 to the voltage at the comparison node 714, and a switching component such as a transistor, transfer gate, or other electronic switch, that couples the comparison component to the output node 712 during the strobe time, and decouples the comparison component from the output node 712 outside of the strobe time. For example, in one embodiment, the strobe time may correspond to a strobe signal that controls a switching component, and the strobe time may be from when the strobe signal turns the switching component on, to when the strobe signal turns the switching component off. In certain embodiments, decoupling a comparison component from the output node 712 outside of the strobe time may allow the voltage at the sense node 708 to vary without affecting the output, while the current to voltage conversion circuit 706 is in the process of converting the input current to a voltage at the sense node 708. Once the current to voltage conversion circuit 706 has produced the analog voltage result at the sense node 708, the strobe time may then occur so that the analog voltage result is converted to a digital result.

In various embodiments, the voltage to digital conversion circuit 710 may convert the analog voltage at the sense node 708 to a digital signal in various ways, based on the voltage difference between the sense node 708 and the comparison node 714. For example, in one embodiment, the voltage to digital conversion circuit 710 may include a transistor that turns on or off based on a gate-to-source voltage, where the gate (or source) of the transistor is coupled to the sense node 708, and where the source (or gate) of the transistor is coupled to the comparison node 714. In another embodiment, the voltage to digital conversion circuit 710 may include a comparator, and the input terminals of the comparator may be coupled to the sense node 708 and the comparison node 714. In another embodiment, the voltage to digital conversion circuit 710 may include a pair of inverters connected in a loop, with the sense node 708 and the comparison node 714 coupled to opposite sides of the loop so that feedback amplifies the difference between the sense node 708 and the comparison node 714 to digital levels. Various other or further ways of converting an analog voltage to a digital signal based on a comparison will be clear in view of this disclosure.

The bias circuit 716, in the depicted embodiment, is configured to bias the comparison node 714 to a bias voltage other than a reference voltage, at least during the strobe time. A reference voltage, in various embodiments, may be a high or positive supply voltage, a low or negative supply voltage, or a ground or zero voltage. For example, a node biased to Vdd (e.g., positive supply) or Vss (e.g., 0 V or ground) may be referred to as biased to a reference voltage.

In certain embodiments, the bias circuit 716 may include or be coupled to one or more voltage supplies that provide bias voltages. In another embodiment, a bias circuit 716 may include one or more level shifters, voltage regulators, or the like, that produce a bit bias voltage based on a supply voltage. In one embodiment, a bias circuit 716 may include one or more switching components such as transistors, transfer gates, or the like, for coupling or decoupling bias voltages to or from the comparison node 714. In another embodiment, a bias circuit 716 may be directly coupled to the comparison node 714 without an intervening switching component. Various ways of providing a bias voltage at the comparison node 714 will be clear in view of this disclosure.

In certain embodiments, biasing the comparison node 714 to a voltage other than a reference voltage may improve the sensitivity and/or reliability of the voltage to digital conversion circuit 710. For example, in certain embodiments, the voltage to digital conversion circuit 710 may have a comparison threshold, so that the digital output is one (or zero) if the voltage difference between the sense node 708 and the comparison node 714 is above the threshold, and zero (or one) if the difference is below the threshold. In further embodiments, the comparison threshold may be physically built in to the voltage to digital conversion circuit 710. For example, if the voltage to digital conversion circuit 710 uses a transistor with the gate coupled to the sense node 708, then the threshold voltage sufficient to turn the transistor on may be a built-in comparison threshold. However, in certain embodiments, the voltages at the sense node 708 for a higher-current bit line (e.g., for a conducting or low-resistance cell) and for a lower-current bit line (e.g., for a non-conducting or high-resistance cell) may both be above the built-in comparison threshold, or may both be below the built-in comparison threshold. Thus, if a sense amplifier 150 were to compare such voltages to a reference voltage of 0 V, the sense amplifier would fail to distinguish between conducting and non-conducting cells, and would produce the same digital output in both cases, leading to data errors.

In certain embodiments, sense amplifier errors that fail to distinguish between conducting and non-conducting memory cells may be avoided by customizing a built-in comparison threshold for the voltage to digital conversion circuit 710. For example, a threshold voltage for a transistor controlled by the voltage at the sense node 708 may be customized to be between the sense node voltage for conducting cells and the sense node voltage for non-conducting cells. However, providing a custom threshold voltage for a transistor or other comparison component may increase the process cost for a memory die. In another embodiment, such errors may be avoided by changing the bias voltages for sense operations, or by changing the design of the current to voltage conversion circuit 706 so that the voltage at the sense node 708 is above or below the built-in comparison threshold depending on whether a cell conducts. However, in certain embodiments, limiting the bias voltages for sense operations may decrease the Vt window 604, thus decreasing storage density or reliability, and redesigning the current to voltage conversion circuit 706 to produce a larger voltage swing at the sense node 708 may increase die size or expense.

By contrast, in the depicted embodiment, biasing the comparison node 714 to a voltage other than a reference voltage may allow the voltage to digital conversion circuit 710 to distinguish between conducting and non-conducting cells, and may avoid narrowing the Vt window 604, increasing die size for a memory device, or increasing die expense to customize a built-in comparison threshold of the voltage to digital conversion circuit 710.

The bias circuit 716, in certain embodiments, may bias the comparison node 714 to the bias voltage at least during the strobe time. In one embodiment, the bias circuit 716 may provide a constant bias voltage, so that the comparison node 714 is biased during the strobe time and at other times. In another embodiment, the bias circuit 716 may turn the bias voltage on or off at times other than the strobe time, or may supply another voltage used by the voltage to digital conversion circuit 710 at times other than the strobe time, but may provide the bias voltage at least from when the strobe time begins to when the strobe time ends, so that the comparison and output performed by the voltage to digital conversion circuit 710 are based on a comparison to the bias voltage, not based on a comparison to 0 V, Vdd, or another reference voltage.

In certain embodiments, the bias voltage applied to the comparison node 714 by the bias circuit 716 may be between a positive supply voltage (e.g., Vdd) and ground (e.g., Vss, or 0 V). In further embodiments, the bias voltage may be within a range from 0.1 volts to 0.5 volts (relative to Vss, ground, or another reference voltage). In a further embodiment, the bias voltage applied to the comparison node 714 by the bias circuit 716 may be within a range from 0.2 volts to 0.3 volts (relative to Vss, ground, or another reference voltage). In certain embodiments, the bias voltage may decrease the voltage difference between the sense node 708 and the comparison node 714 during the strobe time. As used herein, decreasing the voltage difference between the sense node 708 and the comparison node 714 may refer to a decrease, relative to a voltage difference that would have existed if the comparison node 714 were biased to a reference voltage. For example, if the voltage at the sense node 708 is positive, a positive bias voltage, between 0 V and the sense node voltage, may be referred to as decreasing the voltage difference between the sense node 708 and the comparison node 714. Conversely, if the voltage at the sense node 708 is negative, a negative bias voltage, between 0 V and the sense node voltage, may be referred to as decreasing the voltage difference between the sense node 708 and the comparison node 714. However, the actual voltage difference between the sense node 708 and the comparison node 714 may be approximately constant during the strobe time.

Additionally, in certain embodiments, the bias circuit 716 may isolate the comparison node 714 from ground noise. In various embodiments, ground noise may refer to any voltage other than 0 V that occurs on a nominally 0 V ground line. In certain embodiments, for example, small ground lines for dense non-volatile memory arrays may have significant resistance, and voltage at one point on a ground line may be pulled up by current through the ground line. Ground noise may also be caused by capacitive coupling between the ground line and other components, or the like. In certain embodiments, if a comparison node 714 for a sense amplifier 150 is coupled directly to a ground line, then ground line noise may introduce transient non-zero voltages at the comparison node 714, potentially affecting the digital result at the output node 712. By contrast, a bias circuit 716 that provides a bias voltage other than a reference voltage may reduce noise at the comparison node 714, or isolate the comparison node 714 from ground. For example, in certain embodiments, internal capacitance of the bias circuit 716 may smooth the output of the bias circuit 716. Various further ways to use a bias circuit 716 to isolate the comparison node 714 from ground noise will be clear in view of this disclosure.

FIG. 8 is a schematic block diagram illustrating a further embodiment of a sense amplifier 150. The sense amplifier 150, in the depicted embodiment, may be substantially similar to the sense amplifier 150 described above with reference to FIG. 7, including a bit line bias circuit 702, a BLI node 704 coupled to a bit line, a current to voltage conversion circuit 706, a sense node 708, a voltage to digital conversion circuit 710, an output node 712, a comparison node 714, and a bias circuit 716 substantially as described above.

The current to voltage conversion circuit 706, in the depicted embodiment, includes a capacitor 806, an isolation transistor 802, a precharge circuit 804, and a boost circuit 808. In general, in various embodiments, the current to voltage conversion circuit 706 may convert a bit line current to a voltage at the sense node 708 by coupling the capacitor 806 to the bit line for a predetermined period of time, so that the bit line current charges or discharges the capacitor 806.

In various embodiments, the capacitor 806 may be a metal-insulator-metal capacitor, a metal-oxide-semiconductor capacitor, or any other component with a capacitance, such as a reverse-biased diode or the like. In certain embodiments, the capacitor 806 may be disposed in one or more metal interconnect layers for a die 212, or may be a transistor (e.g., in a CMOS layer for the die 212), used as a capacitor 806 by coupling source and drain terminals together so that a gate dielectric provides capacitance between the gate and the coupled source/drain terminals. In further embodiments, the capacitor 806 is coupled to the sense node 708. For example, in the depicted embodiment a first terminal of the capacitor 806 is coupled to the sense node 708, and a second terminal of the capacitor 806 is coupled to the boost circuit 808. In various embodiments, a current sourced from (or sinked by) the capacitor 806) may charge or discharge the capacitor 806, resulting in a voltage change at the sense node 708.

The isolation transistor 802, in the depicted embodiment, is configured to couple the sense node 708 to the current (e.g., a bit line current or other current coupled to the sense amplifier 150 at the BLI node 704) for a predetermined time, referred to as a sense time. For example, in the depicted embodiment, the isolation transistor 802 is an n-channel metal-oxide-semiconductor (NMOS) transistor controlled by the XXL signal, and the XXL signal may be driven high (e.g., by the die controller 220, state machine 222, read/write circuits 230 or the like) during the predetermined sense time, to turn the isolation transistor 802 on and couple the sense node 708 to the current. The XXL signal may go high to turn the isolation transistor 802 on at the beginning of the predetermined sense time, and may go low to turn the isolation transistor 802 off at the end of the predetermined sense time. In another embodiment, the isolation transistor 802 may be a p-channel metal-oxide-semiconductor (PMOS) transistor, and the XXL signal may be driven low during the predetermined sense time. In another embodiment, the isolation transistor 802 may be another type of transistor, or another switching component such as a transfer gate may take the place of the isolation transistor 802.

In certain embodiments, the isolation transistor 802 may couple the capacitor 806 at the sense node 708 to a bit line 302 (e.g., via the BLI node 704) for a predetermined sense time. In various embodiments, coupling the sense node 708 and the capacitor 806 to a bit line 302, a bit line current, or any other current at the BLI node 704 may result in the sense node voltage being affected by the coupled current discharging or charging the capacitor 806. For example, if a bit line current is sourced from the sense node 708, discharging the capacitor 806 during the predetermined sense time, then the capacitor 806 will be discharged by a charge amount equal to the integral of the bit line current over the sense time, resulting in a voltage change at the sense node 708 directly proportional to the charge amount (and inversely proportional to the capacitance of the capacitor 806). Thus, in certain embodiments, the voltage at the sense node 708 may be based on the bit line current in response to the isolation transistor 802 coupling the capacitor 806 to a bit line 302 for the predetermined sense time. For example, after the predetermined sense time, the voltage at the sense node 708 may correspond to the charge remaining on the capacitor 806, which in turn corresponds to the bit line current and the state of the cell being sensed.

The predetermined sense time, in certain embodiment, may be determined or selected by a manufacturer of the sense amplifier 150 based on the range of expected currents and the capacitance of the capacitor 806. For example, in one embodiment, a long sense time may result in a low-capacitance capacitor 806 being fully discharged by a bit line current, regardless of whether the current is a higher current for a conducting or low-resistance cell, or a lower current for a non-conducting or high-resistance cell. Conversely, in another embodiment, a short sense time may result in a higher-capacitance capacitor 806 being insufficiently discharged by a bit line current. Accordingly, in certain embodiments, the manufacturer may predetermine the length of the sense time so that different currents at the BLI node 704 result in detectably different voltages at the SEN node 708, with the capacitor 806 neither under- or over-discharged.

In certain embodiments, as described above with reference to FIGS. 4 and 5, a sense amplifier 150 may be coupled to a bit line 302 of a memory array, and the current coupled to the sense amplifier may be a bit line current through a memory cell from the bit line 302 to a cell source line 316. For example, FIGS. 4 and 5 depict a bit line 302 at the top of the figure and a cell source line 316 at the bottom of the figure, so a current from a bit line 302 to a cell source line 316 may be in the downward direction, as depicted. In various embodiments, the current may be a higher current if the memory cell is in a conducting or low-resistance state (given the applied bias voltages) or may be zero, or a lower leakage current if the memory cell is in a non-conducting or high-resistance state (given the applied bias voltages). In further embodiments, a current from a bit line 302 to a cell source line 316 may be in a direction away from the sense amplifier 150 coupled to the bit line, so the current sensed by the sense amplifier 150 may be sourced from, rather than sinked by, the sense amplifier 150, and may discharge, rather than charge, the capacitor 806

As described above with reference to FIG. 5, the voltage at the cell source line 316 may be positive during a sense operation. For example, for negative threshold voltage sensing, the cell source line 316 may be biased to a positive read voltage Vread, and the control gate of the selected cell may be biased to zero volts. Additionally, to produce a current out from the sense amplifier 150, to the cell source line 316 via the bit line 302, so that the current discharges the capacitor 806, the current to voltage conversion circuit 706 may be configured to bias the sense node 708 to a bias voltage higher than the voltage at the cell source line 316. For example, in one embodiment, the bit line 302 may be biased to a higher voltage than the cell source line 316, and the sense node 708 may be biased to a higher voltage than the bit line 302. (In certain embodiments, the bit line bias circuit 702 may provide an initial bias voltage for the bit line 302, but may then decouple from the bit line at least during the sense time, so that the bit line current is sourced from the sense node 708 rather than from the bit line bias circuit 702. In another embodiment, the bias voltage for the bit line may be provided by the current to voltage conversion circuit 706).

In certain embodiments the current to voltage conversion circuit 706 may bias the sense node 708 to a bias voltage higher than the voltage at the cell source line 316 using the precharge circuit 804 and the boost circuit 808. The precharge circuit 804, in certain embodiments, may be configured to precharge the sense node 708 to a precharge voltage.

In certain embodiments, the precharge circuit 804 may include or be coupled to one or more voltage supplies that provide a precharge voltage. In another embodiment, a precharge circuit 804 may include one or more level shifters, voltage regulators, or the like, that produce a precharge voltage based on a supply voltage. In one embodiment, a precharge circuit 804 may include one or more switching components such as transistors, transfer gates, or the like, for coupling or decoupling bias voltages to or from the sense node 708. Various ways of providing a precharge voltage at the sense node 708 will be clear in view of this disclosure. In certain embodiments, the precharge circuit 804 may be coupled to the sense node 708 (e.g., via a switching component) to precharge the capacitor 806, raising the sense node voltage to a precharge voltage, and then may be de-coupled from the sense node 708 at or before the sense time, so that the sense node voltage is no longer driven by the precharge circuit 804, and instead changes as the capacitor 806 discharges.

In certain embodiments, the precharge voltage may be a bias voltage selected configured by a manufacturer of the sense amplifier 150 for precharging the sense node 708. In certain embodiments, as described above with reference to FIG. 7, the voltage to digital conversion circuit 710 may convert the analog voltage at the sense node 708 to a digital signal based on a voltage difference between the sense node 708 and the comparison node 714 during the strobe time. An effective threshold voltage for the voltage to digital conversion circuit 710 may be an input voltage at the sense node 708, above which the digital output at the output node 712 is a first value (e.g., a zero or a one), and below which the digital output at the output node 712 is a second value different from the first value (e.g., a one if the first value is a zero or a zero if the first value is a one). In certain embodiments, the effective threshold voltage for the voltage to digital conversion circuit 710 may be a combination (e.g., a sum) of the bias voltage at the comparison node 714 and a built-in comparison threshold. For example, in the depicted embodiment, the sense transistor 816 turns on if the sense node voltage is above the comparison node voltage plus a built-in threshold voltage for the sense transistor 816 (e.g., if the gate-to-source voltage for the sense transistor 816 is above the built-in threshold voltage for the sense transistor 816).

The precharge circuit 804, in certain embodiments, may be configured to precharge the sense node 708 to a precharge voltage that is above the effective threshold voltage for the voltage to digital conversion circuit 710. In certain embodiments, the precharge voltage may be higher than the effective threshold voltage for the voltage to digital conversion circuit 710, by an offset or margin. In certain embodiments, a low leakage current for a non-conducting or high-resistance cell may discharge the capacitor 806 to some extent during the sense time, but precharging the sense node 708 to a precharge voltage that is higher than the effective threshold voltage for the voltage to digital conversion circuit 710, by an offset or margin may prevent the sense node voltage from falling below the effective threshold voltage. In further embodiments, a higher current for a conducting or low-resistance cell may discharge the capacitor 806 to a greater extent during the sense time, so that the sense node voltage falls below the effective threshold voltage, changing the digital output at the output node 712.

Thus, in certain embodiments, the precharge voltage may be constrained by the effective threshold voltage for the voltage to digital conversion circuit 710. If the precharge voltage is too low, the sense node voltage at the end of the sense time may be below the effective threshold voltage for the voltage to digital conversion circuit 710, regardless of whether the bit line current is high or low. Conversely, if the precharge voltage is too high, the sense node voltage at the end of the sense time may be above the effective threshold voltage for the voltage to digital conversion circuit 710, regardless of whether the bit line current is high or low. In either case, the sense amplifier 150 may fail to distinguish between conducting (or low resistance) and non-conducting (or high-resistance) cells, and may produce erroneous results. Accordingly, in certain embodiments, the precharge circuit 804 may be configured to produce a precharge voltage that is above the effective threshold voltage for the voltage to digital conversion circuit 710 by a margin that is sufficiently high to avoid detecting leakage current as a high bit line current, but that is sufficiently low that the sense node voltage at the end of the sense time is below the effective threshold voltage if the capacitor 806 is discharged by a high bit line current for a conducting or low-resistance cell.

As described above, the sense node 708 may be biased to a higher voltage than the bit line 302, which in turn may be biased to a higher voltage than the cell source line 316, in order to produce a current through a conducting memory cell to the cell source line 316 that discharges the capacitor 806 during the sense time. However, the precharge voltage, constrained by the effective threshold voltage for the voltage to digital conversion circuit 710, may be insufficient to produce a current or to produce a large enough current that the voltage drop at the capacitor 806 is detected). Accordingly, in certain embodiments, the boost circuit 808 may boost the sense node voltage further above the precharge voltage at least during the sense time, to produce a current, and may un-boost the sense node voltage after the sense time, so that the sense node voltage at the end of the sense time reflects the discharge of the capacitor 806 relative to the initial precharge voltage, rather than relative to the boosted voltage.

In a certain embodiment, the boost circuit 808 may be configured to couple a clock signal to the capacitor 806 across from the sense node 708. For example, in the depicted embodiment, the capacitor 806 is connected between the sense node 708 and the sense amplifier clock (CLKSA) node, and the boost circuit 808 is coupled to the CLKSA node (e.g., the opposite side of the capacitor 806 from the sense node 708).

In certain embodiments, a clock signal may refer to a signal that alternates between high and low levels (e.g., between a positive supply voltage Vdd and 0 volts, ground or Vss). In certain embodiments, a clock signal may be a signal that alternates between high and low levels with a fixed or predetermined frequency. In another embodiment a clock signal may include pulses that occur with rising and/or falling edges controlled by the die controller 220, state machine 222, read/write circuits 230, or the like, rather than at a fixed frequency.

In certain embodiments, the boost circuit 808 may include a clock generator that produces the clock signal, or may be coupled to an external clock generator. In further embodiments, the boost circuit 808 may include switching components such as transistors, transfer gates, or the like, that couple or decouple the clock signal to the sense node 708. In another embodiment, the boost circuit 808 may permanently couple the clock signal to the sense node 708. In one embodiment, the boost circuit 808 may include or be coupled to one or more voltage supply lines, voltage regulators, or the like that provide the high and low levels for the clock signal, and may use switching components such as transistors to output the high clock level or the low clock level to the sense node 708. Various other or further ways of coupling a clock signal to a sense node 708 will be clear in view of this disclosure.

In certain embodiments, coupling a clock signal to the capacitor 806 across from the sense node 708 may result in the sense node voltage being boosted by a boost amount when the clock signal is high. Thus, in certain embodiments, biasing the sense node 708 to a bias voltage sufficiently higher than the bit line voltage and the cell source line voltage may include using the precharge circuit 804 to precharge the sense node 708 to the precharge voltage when the clock signal is low, then using the boost circuit 808 to bias the sense node 708 to the precharge voltage plus the boost amount when the clock signal is high.

In a further embodiment, the sense time for the current to voltage conversion circuit 710 may occur while the clock signal is high, allowing the capacitor 806 to be discharged if the selected cell conducts. After the sense time, the clock signal may go low again, and the resulting sense node voltage, lower than the precharge voltage by the amount of capacitor discharge, may be converted to a digital result by the voltage to digital conversion circuit 710.

The boost amount provided by the boost circuit 808 at the sense node 708 may be related to the magnitude of the clock signal (e.g., the voltage difference between high and low clock levels). However, capacitive coupling between the CLKSA node and the sense node 708 may be imperfect or non-ideal, resulting in a boost amount at the sense node 708 that is smaller than the magnitude of the clock signal. The ratio of the boost amount to the clock signal magnitude may be referred to herein as a coupling ratio for the capacitor 806. For example, if the capacitor 806 couples a 1 volt clock signal at the CLKSA node to the sense node 708, resulting in a voltage boost of 0.7 volts at the sense node 708 when the clock signal goes high, then the coupling ratio is 70%.

In certain embodiments, the magnitude of the clock signal may be limited by available supply voltages at the sense amplifier. For example, a clock signal may alternate between 0 volts, or Vss, and a positive supply voltage Vdd, with a maximum amplitude of Vdd. In another embodiment, a clock signal may use a supply voltage other than Vdd but may still be limited by the magnitude of the supply voltage in use. Consequently, in further embodiments, the magnitude of the boost amount may be limited by both the supply voltage and the coupling ratio. In certain embodiments, the coupling ratio for the capacitor 806 may be under 70%. In one embodiment, the coupling ratio for the capacitor 806 may be between 60% and 65%. In a further embodiment, the coupling ratio for the capacitor 806 may be under 60%.

In certain embodiments, therefore, the maximum bias voltage at the sense node 708 may be the precharge voltage (constrained by the effective threshold voltage for the voltage to digital conversion circuit 710), plus the boost amount (constrained by the clock amplitude and the coupling ratio). The maximum bias voltage at the cell source line 316, in turn, may be constrained by the maximum bias voltage at the sense node 708 (so that a voltage drop from the sense node 708 to the cell source line 316 is sufficient to produce a current), thus limiting the extent of the Vt window 604 for negative threshold voltage sensing. Improving the coupling ratio to improve the maximum bias voltage at the sense node 708, and the corresponding extent of the Vt window 604, may involve providing a larger capacitor 806, thus increasing the die size and expense of the sense amplifier 150. Instead, in some embodiments, the effective threshold voltage for the voltage to digital conversion circuit 710 may be increased above the threshold voltage of the sense transistor 816 by using the bias circuit 716 to provide a bias voltage at the comparison node 714.

Thus, in various embodiments, providing a bias voltage at the comparison node 714 may raise the effective threshold voltage for the voltage to digital conversion circuit 710, thus raising the constraints on the precharge voltage, and allowing the sense node 708 to be biased to a high supply voltage (e.g., Vdd) rather than to a lower voltage limited by the boost amount. In further embodiments, the bias voltage at the cell source line 316, and the corresponding extent of the Vt window 604 may still be constrained so that a sufficient voltage drop between the sense node voltage (at Vdd) and the cell source line 316 produces a current. However, in certain embodiments, the bias voltage at the cell source line 316 may not be further limited by the coupling ratio of the capacitor 806. Thus, in certain embodiments, providing a bias voltage at the comparison node 714 may improve the range of available bias voltages, thus improving the Vt window 604 for flash memory, or similarly improving the range between read thresholds for memory cells that store data using another alterable physical or electrical property.

The voltage to digital conversion circuit 710, in the depicted embodiment, includes a sense transistor 816. In general, in various embodiments, a sense transistor 816 may be any transistor configured as a switch that turns on or off depending on the voltage at the sense node 708. In the depicted embodiment, the sense transistor 816 is an NMOS transistor that turns on if the voltage at the sense node 708 is high. In another embodiment, a sense transistor 816 may be a PMOS transistor that turns off if the voltage at the sense node 708 is high. In various embodiments, a sense transistor 816 may be an n-channel transistor, a p-channel transistor, an enhancement mode transistor, a depletion mode transistor, a junction field effect (JFET) transistor, or any other transistor or switching element that switches on or off based on an applied voltage.

In certain embodiments a sense transistor 816 may include a source terminal 818, a gate terminal 820, and a drain terminal 814. In further embodiments, the gate terminal 820 may be coupled to the sense node 708. In various embodiments, coupling the gate terminal 820 of a sense transistor 816 to a sense node 708 may allow the sense transistor 816 to be switched on and off by the sense node voltage. In the depicted embodiment, the source terminal 818 is coupled to the comparison node 714 biased by the bias circuit 716. Thus, in certain embodiments, the source terminal 818 of the sense transistor 816 may be biased to a bias voltage other than a reference voltage, at least during the strobe time. In various embodiments, the sense transistor 816 may be turned on or off according to the gate-to-source voltage, so coupling the gate terminal 820 to the sense node 708 and the source terminal 818 to the comparison node 714 may result in the sense transistor 816 turning on or off based on the voltage difference between the sense node 708 and the comparison node 714.

In the depicted embodiment, the sense transistor 816 is an n-channel enhancement mode transistor, for which the source terminal 818 in the absence of a bias voltage would normally be connected to ground, and the bias voltage biases the source terminal 818 above 0 V. In another embodiment, a sense transistor 816 may be a p-channel transistor, for which the source terminal 818 in the absence of a bias voltage would normally be connected to Vdd, and the bias voltage may bias the source terminal 818 away from Vdd. In certain embodiments, the bias voltage may decrease a gate-to-source voltage for the sense transistor 816, relative to an unbiased sense transistor 816 with the source terminal 818 coupled to a reference voltage such as Vdd or Vss. Various other or further ways to configure a sense transistor 816 will be clear in view of this disclosure.

The voltage to digital conversion circuit 710, in the depicted embodiment, includes a strobe transistor 812. The strobe transistor 812, in various embodiments, may be an n-channel transistor, a p-channel transistor, an enhancement mode transistor, a depletion mode transistor, or the like, and may be configured as a switch to couple or decouple the sense transistor 816 from the output node 712. In the depicted embodiment, the strobe transistor 812 is controlled by the STB signal, which turns the strobe transistor 812 on during the strobe time, and off otherwise.

In the depicted embodiment, the sense transistor 816 is controlled by the sense node voltage at the gate terminal 820, and biased at the source terminal 818. Accordingly, in a further embodiment, the strobe transistor 812 is configured to couple or decouple the drain terminal 814 of the sense transistor 816 to the output node 712 to output a data result. In one embodiment the output node 712 may be precharged to a high voltage (e.g., representing a binary one) by the die controller 220, state machine 222, read/write circuits 230 or the like, and then coupled to the sense transistor 816 by the strobe transistor 812 during the strobe time. Thus, in a further embodiment, the output node voltage may remain high if the sense transistor 816 is off during the strobe time, but may be pulled low (e.g., to approximately the bias voltage at the comparison node 714) if the sense transistor 816 is on during the strobe time. Accordingly, in certain embodiments, the difference from the analog voltage produced at the sense node 708 by the current to voltage conversion circuit 706 after the sense time, to the bias voltage at the comparison node 714, may turn the sense transistor 816 on or off, resulting in the output node voltage being kept high or pulled low during the strobe time. The digital signal (e.g., a one or zero) produced by the output node voltage being kept high or pulled low may be latched into data latches 810 as a data result for the sense operation.

The bias circuit 716, in the depicted embodiment, includes a voltage regulator 824. In certain embodiments, a voltage regulator 824 may be coupled to two input voltages, such as a positive supply voltage Vdd 822 and ground 826, and may output a voltage between the two input voltages. The voltage regulator 824 may be configured to produce the bias voltage based on the input voltages, and the output of the voltage regulator 824 may be coupled to the comparison node 714.

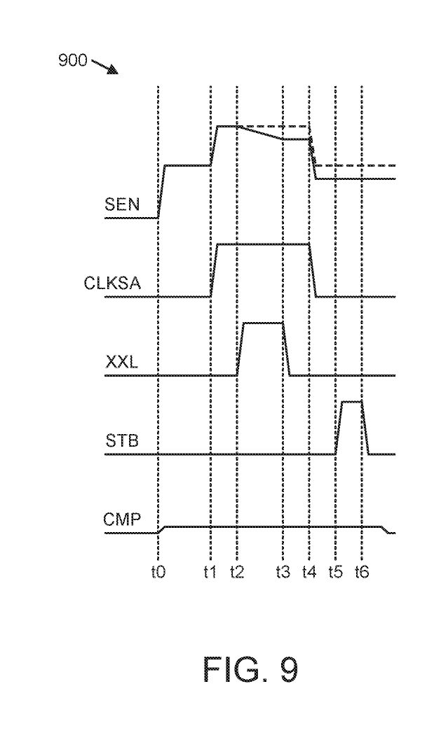

FIG. 9 is a timing diagram 900 illustrating operation of a sense amplifier 150, in one embodiment. The sense amplifier 150 may be substantially similar to the sense amplifier 150 described above with reference to FIG. 8. The timing diagram illustrates voltages (on the vertical axis) over time (on the horizontal axis) for the sense node (SEN) 708, the sense amplifier clock node (CLKSA) across the capacitor 806 from the sense node 708, the XXL signal that controls the isolation transistor 802, the STB signal that controls the strobe transistor 812, and for the comparison node (CMP) 714.

In the depicted timing diagram 900, multiple voltage signals are vertically offset to avoid confusing overlaps. Relative voltage changes are depicted for the individual voltage signals, beginning from zero volts, but the vertical distance between different signals does not signify a voltage difference.

In the depicted embodiment, at time t0, the sense node 718 is biased up from 0 V to a precharge voltage, by the precharge circuit 804. The precharge occurs when the clock signal coupled to the capacitor 806 at the CLKSA node is low. A bias voltage is applied to the comparison node 714. (In certain embodiments, a bias voltage at the comparison node 714 may be constant. In the depicted timing diagram 900, however, signals begin at zero volts for convenience in depiction, and the rising edge at time t0 shows that the bias voltage is non-zero (e.g., 0.1 to 0.5 volts in certain embodiments) at least during the strobe time.

In the depicted embodiment, at time t1, the clock signal coupled to the capacitor 806 at the CLKSA node by the boost circuit 808 goes high, and the voltage at the sense node 708 is boosted by a boost amount. In the depicted embodiment, the boost amount at SEN is less than the clock signal amplitude at CLKSA, due to a coupling ratio less than 100% for the capacitor 806.

In the depicted embodiment, the sense time is from time t2 to time t3. The XXL signal goes high at time t2, turning the isolation transistor 802 on, and goes low at time t3, turning the isolation transistor 802 off again. The SEN voltage remains high (shown by a dashed line) if the bit line current is low, but drops as the capacitor 806 discharges (shown by a solid line) if the bit line current is high. The clock signal at CLKSA remains high during the sense time, but goes low again at time t4, de-boosting the voltage at SEN back to approximately the precharge voltage if the capacitor 806 was not significantly discharged (dashed line) or to below the precharge voltage if the capacitor 806 was significantly discharged (solid line).

In the depicted embodiment, the strobe time is from time t5 to time t6. The bias voltage at CMP is independent of the clock signal at CLKSA, and remains applied at least during the strobe time, even though the clock signal is low during the strobe time. The STB signal goes high at time t5, turning the strobe transistor 812 on, and goes low at time t6, turning the strobe transistor 812 off again. The precharged output node 712 may be discharged through the strobe transistor 812 and the sense transistor 816 during the strobe time if the difference between the SEN voltage and the CMP voltage turns the sense transistor 816 on, into a conducting state (e.g., if a nonconducting cell left the SEN voltage high). However, the output node voltage may remain high if the sense transistor 816 does not conduct, due to a lower voltage difference between SEN and CMP (e.g., if a conductive cell lowered the SEN voltage.)

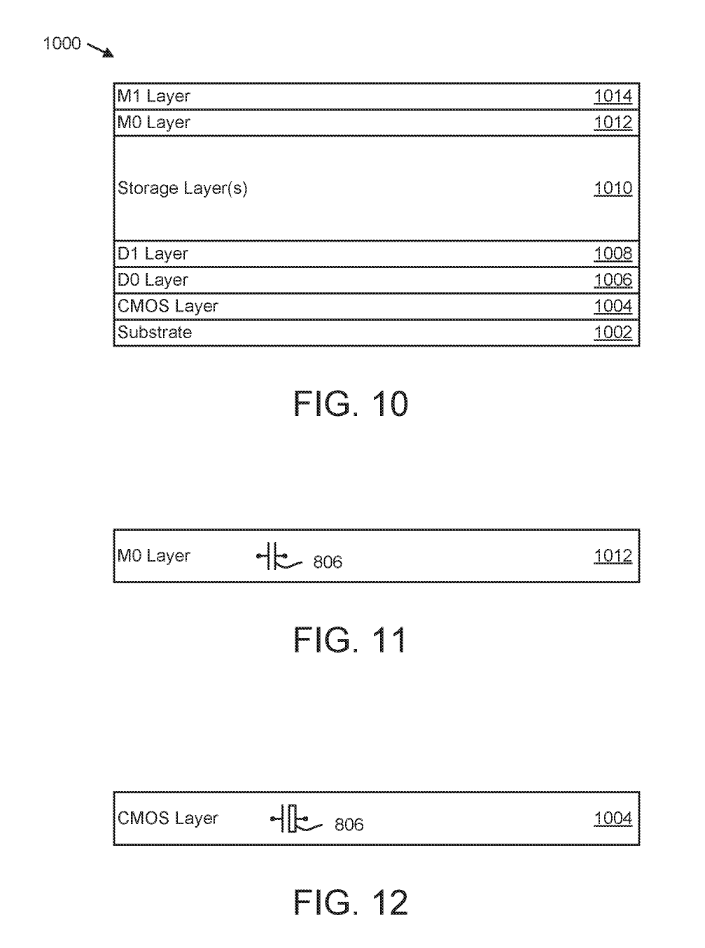

FIG. 10 depicts layers of an integrated circuit 1000 comprising a sense amplifier 150. In certain embodiments, the integrated circuit 1000 may be a chip or die substantially as described above, such as the die 212 described above with reference to FIG. 2. In the depicted embodiment, the integrated circuit 1000 includes a substrate 1002 on which other layers are formed or deposited. In a further embodiment, the integrated circuit includes a layer 1004 formed by a complementary metal-oxide-semiconductor (CMOS) process. The CMOS layer 1004 may include NMOS transistors, PMOS transistors and/or further electronics for the sense amplifier 150 and for other control and logic components of a memory device.

One or more storage layers 1010 may be disposed above the CMOS layer 1004, and may include the memory cells for a memory device, in a single layer for a two-dimensional array, or in multiple layers for a three-dimensional array. In various embodiments, one or more metal interconnect layers may be disposed above and/or below the storage layer(s) 1010. A metal interconnect layer may include conductors (e.g., metal, polysilicon, or the like), which may be separated by insulating material. The conductors of a metal interconnect layer may connect between components of other layers at vertical vias or interconnects. In the depicted embodiment, the integrated circuit includes two metal interconnect layers (the D0 layer 1006 and the D1 layer 1008) below the storage layer(s) 1010 but above the CMOS layer 1004, and two more metal interconnect layers (the M0 layer 1012 and the M1 layer 1014) above the storage layer(s) 1010. In another embodiment, more or fewer metal interconnect layers may be provided above and/or below the storage layer(s) 1010.

FIGS. 11 and 12 depict the M0 layer 1012 (FIG. 11) and the CMOS layer 1004 (FIG. 12) described above with reference to FIG. 10. In one embodiment, the capacitor 806 for a sense amplifier 150, as described above with reference to FIG. 8, may be disposed in one or more metal interconnect layers for an integrated circuit 1000 comprising the sense amplifier 150. For example, in FIG. 11, the capacitor 806 is disposed in the M0 metal interconnect layer 1012. In one embodiment a capacitor 806 may include conductors separated by a dielectric, in a single metal interconnect layer 1012. In another embodiment, a capacitor 806 may include conductors in adjacent metal interconnect layers, separated by an inter-layer dielectric.

In FIG. 12, the capacitor 806 is disposed in a CMOS layer 1004. In one embodiment, a capacitor 806 may be a metal-oxide-semiconductor (MOS) capacitor that includes metal separated from a semiconductor substrate by an oxide dielectric. In the depicted embodiment, the capacitor 806 is a MOS transistor, with source and drain terminals coupled, so that the gate oxide acts as the dielectric between the gate terminal as one side of the capacitor 806 and the coupled source and drain terminals as the other side of the capacitor 806. Forming a capacitor 806 from a transistor of the CMOS layer 1004 or from conductors of one or more metal interconnect layers may result in a small capacitor 806 with a coupling ratio under 70%. However, as described above, biasing a comparison node 714 of a sense amplifier 150 may compensate for a capacitor 806 with a low coupling ratio.

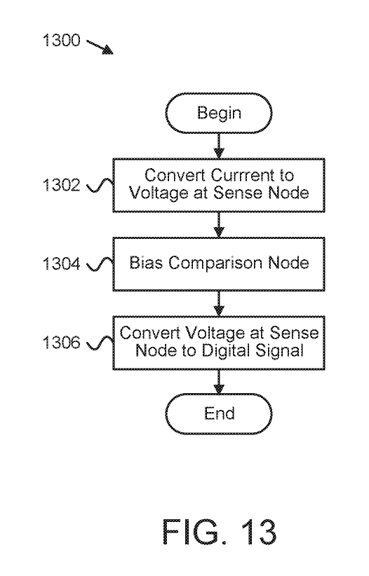

FIG. 13 is a schematic flow chart diagram illustrating one embodiment of a method 1300 for current sensing. The method 1300 begins, and the current to voltage conversion circuit 706 converts 1302 a current coupled to a sense amplifier 150 to an analog voltage at a sense node 708. A bias circuit 716 biases 1304 a comparison node 714 to a bias voltage other than a reference voltage, at least during a strobe time. A voltage to digital conversion circuit 710 converts 1306 the analog voltage at the sense node 708 to a digital signal, based on a voltage difference between the sense node 708 and the comparison node 714, and the method 1300 ends

Means for converting a bit line current to an analog voltage at a sense node 708 of a sense amplifier 150, in various embodiments, may include a current to voltage conversion circuit 706, an isolation transistor 802, a precharge circuit 804, a boost circuit 808, a capacitor 806, a current-sensing resistor, and/or other logic or electronic hardware. Other embodiments may include similar or equivalent means for converting a bit line current to an analog voltage at the sense node 708.

Means for converting an analog voltage to a binary data value based on a voltage difference between the sense node 708 and a comparison node 714 during a strobe time, in various embodiments, may include a voltage to digital conversion circuit 710, a strobe transistor 812, a sense transistor 816, an NMOS transistor, a PMOS transistor, a JFET transistor, an enhancement mode transistor, a depletion mode transistor, a bias component that precharges an output node 712, and/or other logic or electronic hardware. Other embodiments may include similar or equivalent means for converting an analog voltage to a binary data value.

Means for biasing the comparison node 714 to a bias voltage between a positive supply voltage and ground at least during the strobe time, in various embodiments, may include a bias circuit 716, a voltage regulator 824, a level shifter, a voltage supply, and/or other logic or electronic hardware. Other embodiments may include similar or equivalent means for biasing the comparison node 714.

Means for coupling a clock signal to the sense node 708, wherein the bias voltage is independent of the clock signal, in various embodiments, may include a boost circuit 808, a capacitor 806, a clock generator, switching components, and/or other logic or electronic hardware. Other embodiments may include similar or equivalent means for coupling a clock signal to the sense node 708.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. An apparatus comprising:
a sense amplifier comprising:
a current to voltage conversion circuit configured to convert a current coupled to the sense amplifier to an analog voltage at a sense node;
a voltage to digital conversion circuit configured to convert the analog voltage at the sense node to a digital signal based on a voltage difference between the sense node and a comparison node during a strobe time; and
a bias circuit configured to bias the comparison node to a bias voltage other than a reference voltage at least during the strobe time.

2. The apparatus of claim 1, wherein the voltage to digital conversion circuit comprises a sense transistor, the sense transistor comprising a source terminal, a gate terminal, and a drain terminal, the gate terminal coupled to the sense node and the source terminal coupled to the comparison node.

3. The apparatus of claim 1 wherein the bias voltage decreases the voltage difference between the sense node and the comparison node during the strobe time

4. The apparatus of claim 1, wherein the bias voltage is within a range from 0.1 volts to 0.5 volts.

5. The apparatus of claim 1, wherein the current to voltage conversion circuit comprises:
a capacitor coupled to the sense node;
a boost circuit configured to couple a clock signal to the capacitor across from the sense node such that a sense node voltage is boosted by a boost amount when the clock signal is high;
a precharge circuit configured to precharge the sense node to a precharge voltage when the clock signal is low; and
an isolation transistor configured to couple the sense node to the current for a predetermined sense time such that the sense node voltage is affected by the current, wherein the clock signal is high during the predetermined sense time.

6. The apparatus of claim 5, wherein the bias voltage is independent of the clock signal.

7. The apparatus of claim 5, wherein a coupling ratio for the capacitor is under 70%.

8. The apparatus of claim 5, wherein the capacitor is disposed in one or more metal interconnect layers for an integrated circuit comprising the sense amplifier.

9. The apparatus of claim 5, wherein the capacitor comprises a metal-oxide-semiconductor (MOS) transistor with coupled source and drain terminals.

10. The apparatus of claim 1, wherein the sense amplifier is coupled to a bit line of a memory array, and the current is a bit line current through a memory cell from the bit line to a cell source line.

11. The apparatus of claim 10, wherein a voltage at the cell source line is positive.

12. The apparatus of claim 11, wherein the current to voltage conversion circuit is configured to bias the sense node to a bias voltage higher than the voltage at the cell source line, to produce the current.

13. The apparatus of claim 1, wherein the bias circuit isolates the comparison node from ground noise.

14. A system comprising:
an array of memory cells that store data, the memory cells coupled to bit lines such that bit line currents during a sense operation correspond to memory cell states; and
a plurality of sense amplifiers that output data results based on the bit line currents, wherein a sense amplifier comprises:
a capacitor coupled to a sense node;
an isolation transistor that couples the capacitor to a bit line for a predetermined sense time such that a voltage at the sense node is based on a bit line current; and
a sense transistor that outputs a data result during a strobe time based on a gate to source voltage, wherein a gate of the sense transistor is coupled to the sense node and a source terminal of the sense transistor is biased to a bias voltage other than a reference voltage at least during the strobe time.

15. The system of claim 14, wherein the sense amplifier further comprises a voltage regulator configured to provide the bias voltage.

16. The system of claim 14, wherein the bias voltage decreases a gate-to-source voltage for the sense transistor.

17. The system of claim 14, the bias voltage is within a range from 0.1 volts to 0.5 volts.

18. The system of claim 14, wherein the capacitor couples a clock signal to the sense node with a coupling ratio under 70%.

19. An apparatus comprising
means for converting a bit line current to an analog voltage at a sense node of a sense amplifier;
means for converting the analog voltage to a binary data value based on a voltage difference between the sense node and a comparison node during a strobe time;
means for biasing the comparison node to a bias voltage between a positive supply voltage and ground at least during the strobe time

20. The apparatus of claim 19, further providing means for coupling a clock signal to the sense node, wherein the bias voltage is independent of the clock signal.
